(19) United States
(12) Patent Application Publication
(10) Pub. No.: US 2025/0253826 A1
(43) Pub. Date: Aug. 7, 2025

(54) SEALED-CAVITY BULK ACOUSTIC-WAVE RESONATOR AND METHOD FOR MANUFACTURING

(71) Applicant: The Hong Kong University of Science and Technology, Kowloon (HK)

(72) Inventors: Yansong YANG, Clear Water Bay (HK); Jiashuai XU, Clear Water Bay (HK)

(21) Appl. No.: 19/044,970

(22) Filed: Feb. 4, 2025

Related U.S. Application Data
(60) Provisional application No. 63/551,051, filed on Feb. 7, 2024.

(51) Int. Cl. H03H 9/17; H03H 3/02; H03H 9/05; H03H 9/15

(52) U.S. Cl. CPC H03H 9/174; H03H 3/02; H03H 9/0514; H03H 2003/023; H03H 2003/027; H03H 2009/155

(57) ABSTRACT

Described is a technology that facilitates fabrication of an acoustic wave resonator. For instance, an acoustic wave resonator can comprise a silicon layer comprising a base surface, a multi-layer film disposed at the silicon layer opposite the base surface and comprising a metal electrode and a piezoelectric material, and a cavity within the silicon layer, wherein the cavity is sealed, at a location opposite the base surface, by a silicon membrane. The silicon layer and the silicon membrane can be provided as a unitary silicon element. In another instance, a batch of the acoustic wave resonators can be fabricated using a common silicon-on-insulator wafer platform.

### CROSS REFERENCE TO RELATED APPLICATION

This is a nonprovisional claiming priority under 35 U.S.C. § 119 of U.S. Provisional Patent Application No. 63/551,051, filed on Feb. 7, 2024, and entitled “Sealed-Cavity Bulk Acoustic-Wave Resonator and Method for Manufacturing,” the entirety of which priority application is hereby incorporated by reference herein.

### BACKGROUND

Microacoustic devices are a class of micrometer/nanometer-scale electroacoustic components designed to generate, sense, control, or utilize acoustic waves. With the integration of piezoelectric materials and micro-electro-mechanical systems (MEMS) technology, microacoustic devices are being developed including one or more of an acousto-optic modulator, quantum acoustic microsystem, piezoelectric micromachined ultrasound transducer (PMUT), radio frequency (RF) acoustic resonators, etc.

### SUMMARY

The following presents a simplified summary of the disclosed subject matter to provide a basic understanding of one or more of the various embodiments described herein. This summary is not an extensive overview of the various embodiments. It is intended neither to identify key or critical elements of the various embodiments nor to delineate the scope of the various embodiments. Its sole purpose is to present one or more concepts of the disclosure in a streamlined form as a prelude to the more detailed description that is presented later.

Described herein are one or more frameworks directed to a wafer-level sealed silicon cavity (SSC) integration platform. The SSC platform, and associated fabrication steps comprising employing silicon migration technology (SiMiT) and wet oxidation smoothing, can provide a smooth suspended silicon membrane with adjustable thickness, flexible, and fully-sealed cavity shapes with high density, self-formed acoustic wave confinement steps, high temperature coefficient of frequency (TCF), and highly integrated compatibility with CMOS.

An example acoustic wave resonator can comprise a silicon layer comprising a base surface, a multi-layer film disposed at the silicon layer opposite the base surface and comprising a metal electrode and a piezoelectric material, and a cavity within the silicon layer, wherein the cavity is sealed, at a location opposite the base surface, by a silicon membrane.

An example batch of acoustic wave resonators can be fabricated using a common silicon-on-insulator wafer platform, with each of the acoustic wave resonators comprising a silicon body disposed at the common silicon-on-insulator wafer platform and comprising a silicon layer adjacent the common silicon-on-insulator wafer platform, a cavity defined within the silicon layer, and a silicon membrane sealing the cavity, wherein the silicon layer and the silicon membrane are provided as a unitary silicon element, and a multi-layer film disposed at the silicon membrane opposite the common silicon-on-insulator wafer platform and comprising a pair of metal electrodes separated by a piezoelectric material.

An example method for fabricating an acoustic wave resonator can comprise annealing a silicon wafer comprising a well array resulting in migration of silicon atoms of the silicon wafer and formation of a silicon layer having a cavity therewithin, wherein the annealing the silicon wafer further results in migration of silicon atoms of the silicon wafer forming a silicon membrane extending over and sealing the cavity to result in a sealed cavity, and wherein dimensions of the sealed cavity correspond to specified dimensions of the well array, and applying a multi-layer film at the silicon layer and the silicon membrane.

An example benefit of one or more of the above-indicated example embodiments can be an ability to provide the silicon membrane having different thicknesses in different acoustic wave resonators, even of those manufactured at a common silicon-on-insulator wafer platform. This customization can allow for optimization of stress distribution, achieving control of higher order modes.

Another example benefit of one or more of the above-indicated example embodiments can be an ability to provide customization relative to shape and/or volume of the sealed cavity. That is, the cavity can be provided in different shapes and/or volumes in different acoustic wave resonators, even those manufactured at a common silicon-on-insulator wafer platform. This customization can allow for optimization of stress distribution, achieving control of higher order modes.

Still another example benefit of one or more of the above-indicated example embodiments can be an ability to provide smooth surfaces of the silicon membrane both within the sealed cavity and without. This low root mean square (RMS) roughness can aid in increasing a sealed cavity bulk acoustic wave resonator (S-BAR) quality factor such as by about 400%.

Still further benefits comprise a solution for one or more deficiencies of existing frameworks, the deficiencies comprising a lack of integrated acoustic RF platforms for high-density cavities with low cost, simple process, and controllable arbitrary shapes, as well as coupling-enhanced high-order working modes.

In general, the proposed sealed cavity bulk acoustic wave resonator (S-BAR) working at a second-order asymmetric Lamb wave mode (A2 mode) can have a higher operation frequency than an existing thin film bulk acoustic wave resonator (FBAR) working at a first-order symmetric Lamb wave mode (S1 mode) with a same thick suspended film (non-characteristic for an FBAR).

### BRIEF DESCRIPTION OF THE DRAWINGS

The technology described herein is illustrated by way of example and not limited to the accompanying figures in which like reference numerals indicate similar elements.

FIG. 1 illustrates a block diagram of an example, non-limiting, acoustic wave resonator device, in accordance with one or more example embodiments and/or implementations described herein.

FIG. 2 illustrates a block diagram of an example non-limiting system comprising an example batch of acoustic wave resonator devices, including the acoustic wave resonator device of FIG. 1, and an example manufacturing system, in accordance with one or more example embodiments and/or implementations described herein.

FIG. 3 illustrates a schematic diagram of various example representations of various stages of wafer fabrication, which can result in fabrication of the example device of FIG. 1, in accordance with one or more example embodiments and/or implementations described herein.

FIG. 4 illustrates a set of example fabrication processes that can result in the example device of FIG. 1, in accordance with one or more example embodiments and/or implementations described herein.

FIG. 5 illustrates example SEM and optical images of cavity formation induced by a silicon migration technology (SiMiT) process, in accordance with one or more example embodiments and/or implementations described herein.

FIG. 6 illustrates example top and three-dimensional (3D) laser image view of a fabricated oval S-BAR, such as the device of FIG. 1, in accordance with one or more example embodiments and/or implementations described herein.

FIG. 7 illustrates example micrographs and atomic force microscope (AFM) images of a sealed silicon cavity, in accordance with one or more example embodiments and/or implementations described herein.

FIG. 8 illustrates an example fabricated S-BAR device, such as the device of FIG. 1, and corresponding batch of devices, such as the batch of FIG. 2, in accordance with one or more example embodiments and/or implementations described herein.

FIG. 9 illustrates example simulated resonance characteristics of an S-BAR, such as admittance response of S-BAR with second-order mode enhancement and kₜ² v.s. thickness ratio (α) of AlScN to the whole film, such as the device of FIG. 1, in accordance with one or more example embodiments and/or implementations described herein.

FIG. 10 illustrates example simulated stress distributions of S-BARs, such as devices of FIG. 1 or FIG. 2, with different thickness ratios, in accordance with one or more example embodiments and/or implementations described herein.

FIG. 11A illustrates example displacement mode shapes of the first-order symmetric Lamb wave mode (S1) and second-order asymmetric Lamb wave mode (A2) of an example fabricated S-BAR device, such as the device of FIG. 1, in accordance with one or more example embodiments and/or implementations described herein.

FIG. 11B illustrates example displacement distributions of S1 and A2 modes using an unpatterned AlScN layer in accordance with one or more example embodiments and/or implementations described herein.

FIG. 12 illustrates K² vs. thickness ration (R) of a silicon (Si) thin film and piezoelectric layer for S1 and A2 modes of an example fabricated S-BAR device, such as the device of FIG. 1, and also admittance response of an example fabricated S-BAR device, such as the device of FIG. 1, and admittance response of an example fabricated S-BAR device, such as the device of FIG. 1, in accordance with one or more example embodiments and/or implementations described herein.

FIG. 13 illustrates example measured and modified Butterworth-Van Dyke (MBVD) modeled admittance responses of a fabricated S-Bar device, such as the device of FIG. 1, in an S1 mode and an A2 mode, in accordance with one or more example embodiments and/or implementations described herein.

FIG. 14 illustrates additional example measured and modified Butterworth-Van Dyke (MBVD) modeled admittance responses of a fabricated S-Bar device, such as the device of FIG. 1, in S1 and A2 modes, in accordance with one or more example embodiments and/or implementations described herein.

FIG. 15 illustrates still more additional example measured and modified Butterworth-Van Dyke (MBVD) modeled admittance responses of a fabricated S-Bar device, such as the device of FIG. 1, in S1 and A2 modes, in accordance with one or more example embodiments and/or implementations described herein.

FIG. 16 illustrates an example MBVD model circuit and component parameters, and a quality factor distribution of S-BARs as represented at FIGS. 14 and 15, in accordance with one or more example embodiments and/or implementations described herein.

FIG. 17 illustrates an example process flow diagram of example processes that can be performed by the non-limiting system of FIG. 2, in accordance with one or more example embodiments and/or implementations described herein.

FIG. 18 illustrates a continuation of the example process flow diagram of FIG. 17, in accordance with one or more example embodiments and/or implementations described herein.

FIG. 19 illustrates a block diagram of an example operating environment into which embodiments of the subject matter described herein can be incorporated.

FIG. 20 illustrates a schematic block diagram of an example computing environment with which the subject matter described herein can interact and/or be implemented at least in part.

### DETAILED DESCRIPTION

### Overview

The technology described herein is generally directed towards, for example, devices, systems, and/or methods of manufacture for a thin-film bulk acoustic wave resonator (BAW). In particular, technology described herein is directed to a sealed bulk acoustic resonator (S-BAR) employing silicon migration technology (SiMiT) and wet oxidation smoothing to provide an acoustic wave resonator having a customizable cavity volume, customizable silicon thin-film thickness sealing the cavity, and optimizable quality factor, S1 mode parameters and/or A2 mode parameters.

Put another way, the technology described herein is generally directed towards, for example, a unique and novel platform for a thin film bulk acoustic wave (BAW) resonator, which features predefined sealed cavities, self-formed acoustic boundaries, and compatibility with subsequent fabrication. Different from conventional BAW resonator fabrication methods, the frameworks described herein have simplified fabrication by using silicon migration technology: building freely predefined cavities with self-formed acoustic boundaries without patterning the piezoelectric layer in only two steps (etching and annealing), in one or more embodiments. Additionally, the sealed cavity is sturdy enough to be compatible with subsequent hetero-integrating with other devices. For higher frequency and better electromechanical coupling (K2), the proposed platform can excite the second-order asymmetric Lamb wave mode (A2) in scandium-doped aluminum nitride (Al1-xScxN) film with an optimized stress field. The fabricated devices demonstrate S1 and A2 resonant modes at 1.58 GHz and 3.52 GHz with electromechanical coupling coefficients of 1.47% and 5.12%, respectively.

In existing frameworks, a focus of microacoustic research has increasingly shifted towards integrated systems. In the field of radio-frequency (RF) communications, integrated electro-acoustic modules not only reduce the board area but also significantly reduce the parasitic effects introduced by the wiring and components. In terms of piezoelectric micromachined ultrasound transducer (PMUT), monolithic integration can achieve a high density of transducers and a wide variety of array geometries. Moreover, an integrated solution can be employed to minimize overall system size and to reduce power consumption for wearable or implantable microacoustic devices, such as intravascular ultrasound imaging systems.

However, the compatibility of existing microacoustic platforms presents significant challenges for on-chip integration with other electronic components, such as complementary metal-oxide-semiconductor (CMOS) circuits.

That is, most microacoustic devices use suspended structures on the substrate (e.g., silicon) to support free out-of-plane vibration. To date, two wafer-level platforms and one process have been developed to achieve suspended structures in microacoustic systems: silicon-on-insulator (SOI) wafer platform, cavity silicon-on-insulator (C-SOI) wafer platform, and the sacrificial layer process.

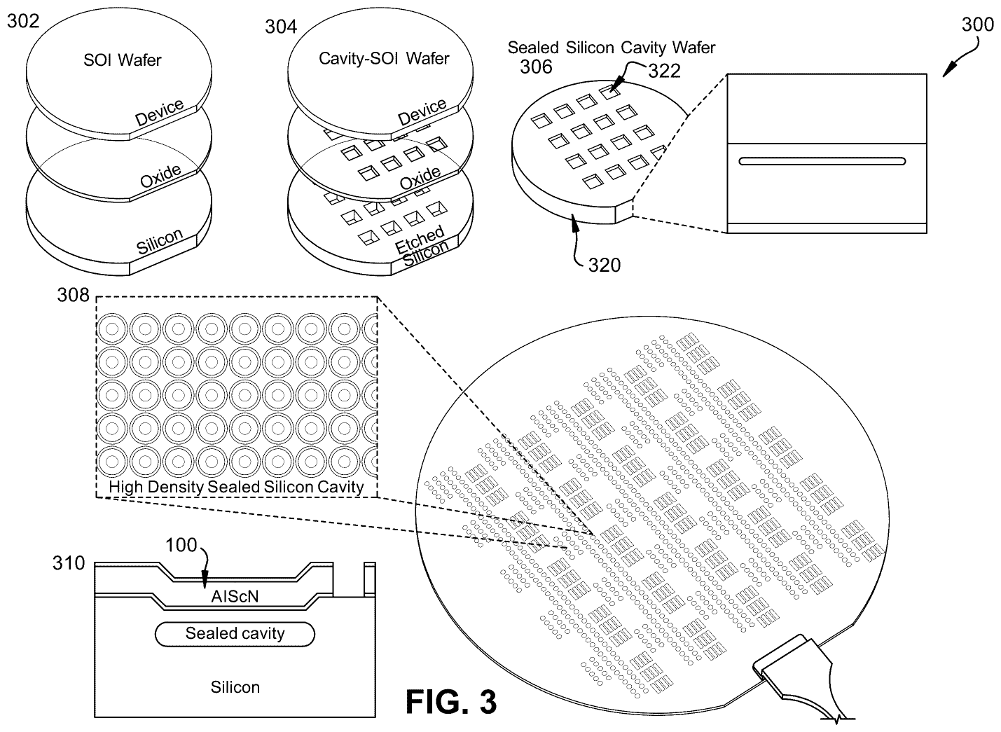

As illustrated at representation 302 of FIG. 3, an SOI wafer platform features three layers: silicon handle substrate, oxide layer, and silicon device layer. As a platform for a post-CMOS integration solution, a SOI wafer platform combined with a back etching process can be used for a carrier substrate of thin film bulk acoustic resonator (FBAR) and PMUT of existing frameworks. The back etching process can selectively remove the silicon substrate to create a hollowed-out region and form the suspended structure in a final act of fabrication. The process has the drawback of weakening the wafer, making it susceptible to breakage, and thus implicating additional support material. Additionally, the aspect ratio constraints of backside etching implicates a larger effective area for each device, thereby reducing the number of devices obtainable per wafer.

In contrast to backside etching, the releasing process is another approach for suspended mechanical acoustic structures on SOI wafers by front etching. The construction of the suspended structure is achieved by isotropic dry etching of the substrate through release windows. A disadvantage of this approach is that the etching boundaries of the release area cannot be accurately defined due to often uncontrollable isotropic etching. Further, this approach can lead to incompatibility issues between etchant and device material and can hinder further microfabrication.

Differently, C-SOI technology was invented to overcome the shortcomings of the SOI platform in microacoustic devices. As illustrated at representation 304 of FIG. 3, a C-SOI wafer can be a pre-CMOS integration platform featuring pre-etched cavities within the handle silicon. This approach can mitigate potential damage to other components from the final etch in the post-CMOS process and can have good compatibility with CMOS technology. The advent of PMUT based on C-SOI wafers has led to a breakthrough in ultrasonic fingerprint recognition technology. Nevertheless, this process requires wafers to have high uniformity for the uniform operating frequency of the microacoustic device, which leads to a higher manufacturing cost for the C-SOI wafer.

The sacrificial layer process is the third mainstream process for MEMS microacoustic devices. The sacrificial layer is created before device fabrication and is removed after device fabrication to achieve device suspension. However, this method implicates a complex multi-layer manufacturing process and further implicates adding a sealing layer for etching holes to ensure the feasibility of subsequent integration processes.

In summary, there are currently very few on-chip integration platforms for low-cost, simple process, CMOS-compatible, and high-density suspended microacoustic devices, and each has deficiencies as noted above. Each also has the deficiency of building a sealed cavity (e.g., an air cavity, in a last step through isotropic wet or dry etching, leading to incompatibility issues between the etchant and device materials and preventing further micromachining and/or heterointegration.

To make up for one or more of the deficiencies noted above, provided herein in one or more example embodiments, is a wafer-level sealed silicon cavity (SSC) inter-CMOS microacoustic platform such as illustrated at representation 306 of FIG. 3. The SSC wafer can comprise a smooth suspended silicon membrane with controllable thickness, customizable cavity shapes with high density (see, e.g., representation 308 of FIG. 3), self-forming acoustic wave confinement steps, and/or high temperature coefficient of frequency (TCF) for acoustic resonators.

The construction of the SSC can be realized by deep reactive-ion etching (DRIE) and a rapid annealing process with low cost and simple steps. Different from a hydrogen annealing smoothing process of existing frameworks, a wet oxidation-based surface smoothing process can be employed for the SSC wafer, achieving a root mean square (RMS) roughness of about 1.5 nm on a cavity internal surface (e.g., a surface of a silicon layer defining the cavity). The flat cavity surface and/or surface external to the cavity can aid in providing a subsequent high-quality material film deposition. In addition, the SSC platform can be compatible with CMOS and can realize microelectromechanical systems (MEMS) and CMOS simultaneous fabrication. Further, a bi-layer film can be employed to excite higher order modes with K² enhancement, rather than using a single piezoelectric film with which the higher order modes feature degraded K².

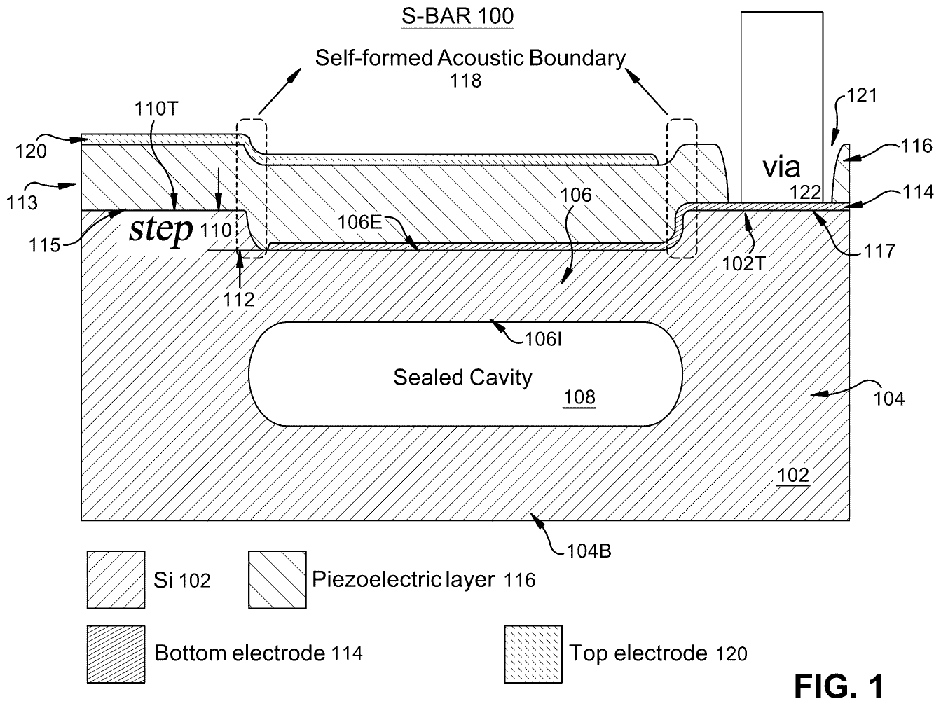

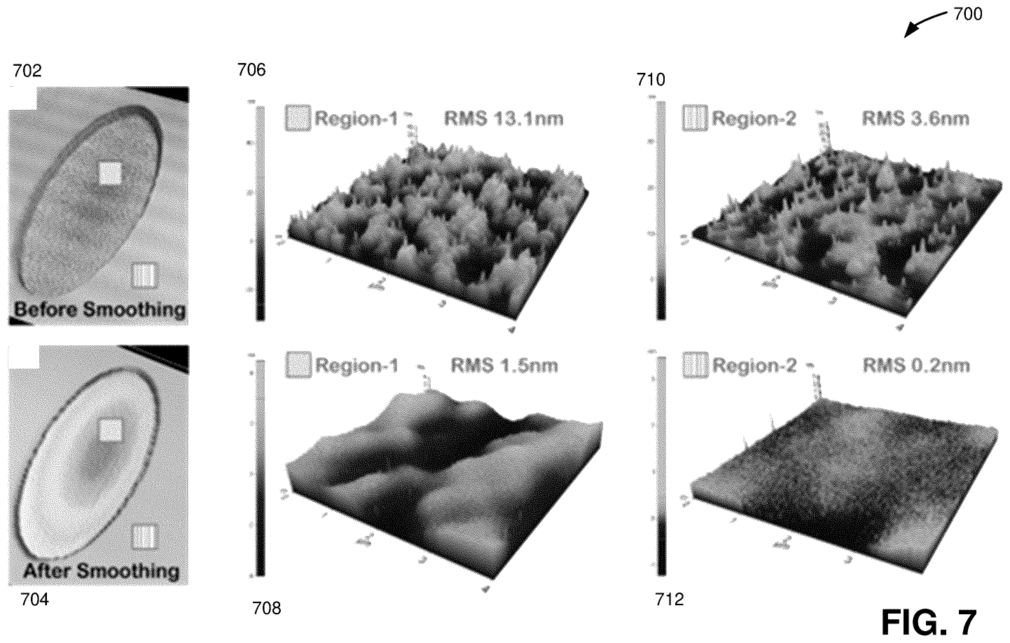

Based on the presented SSC platform, provided herein are one or more example embodiments of a fabricated and characterized, high-order mode enhanced Al_{0.75}SC_{0.25}N sealed cavity bulk acoustic wave resonator (S-BAR), such as illustrated at representation 300 of FIG. 3 and device 100 of FIG. 1, to be discussed in detail below. Corresponding measured data (e.g., FIGS. 7, 8 and 12-16) illustrate that the fabricated S-BARs can achieve a maximum quality factor (Q) of 439, a peak piezoelectric coupling coefficient (kₜ²) of 9.85%, and/or a TCF of −13.2 ppm/K for asymmetric second order (A2) Lamb mode. These results demonstrate that the proposed SSC platform can provide an integrated microacoustic platform to replace C-SOI for ultrasound and microwave applications.

Put another way, an example S-BAR described herein can provide for any one or more of the following.

An example wafer-level sealed silicon cavity inter-CMOS platform for integrated microacoustic devices can result in a smooth suspended silicon membrane, controllable membrane thickness, freely definable cavity shape, and/or self-formed acoustic wave confinement steps.

A wet oxidation-based surface smoothing process for the SSC wafer can achieve a root mean square (RMS) roughness of 1.5 nm on the cavity surface. The flat cavity surface can support the subsequent high-quality material film deposition.

A sealed cavity bulk acoustic wave resonator (S-BAR) based on Al_{0.75}SC_{0.25}N can be provided. The asymmetric second-order (A2) Lamb mode of the S-BAR can be enhanced by optimizing the stress field distribution of the S-BAR. The A2-mode of the S-BAR can achieve a maximum quality factor (Q) of 439, a maximum piezoelectric coupling coefficient (kₜ²) of 9.85%, and/or a TCF of −13.2 ppm/K.

Put very generally, benefits of the one or more embodiments described herein can comprise a sealed cavity, simple fabrication, low cost, controllable acoustic boundary, high density, high compatibility with existing components, high frequency, and/or temperature compensation, without being limited thereto.

Applications can comprise RF microwave, ultrasound, acoustic filters for wireless communication, high-speed wireless communication system (e.g., full-integrated RF front-end modules for 6G), and/or medical applications (e.g., ultrasonic high-density transducers for cancer treatment), without being limited thereto.

### Terminology

As used herein, the terms “cost” or “expense” can refer to power, memory, and/or processing power.

As used herein, the term “data” can comprise “metadata.”

Reference throughout this specification to “embodiment,” “one embodiment,” “an embodiment,” “one implementation,” and/or “an implementation,” means that a feature, structure, or characteristic described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the features, structures, or characteristics may be combined in any suitable manner in one or more embodiments/implementations.

As used herein, the terms “employing” or “employed by” can refer to an element (e.g., a hardware device) that is currently being employed, that has already been employed and/or that is to be employed.

As used herein, the term “entity” can refer to a machine, device, smart device, component, hardware, software, and/or human. A “user entity,” “client entity” or “administrative entity” can refer to an entity that employs one or more outputs of a system described herein for personal, public, consumer, business, and/or commercial use. that stores and accesses data/metadata at a network access storage system.

As used herein, the term “group” can refer to one or more.

A “group of hardware” or “equipment” can refer to a subset of hardware devices of an operation system, which hardware devices can comprise, but are not limited to, storage nodes, switch nodes, server nodes and/or corresponding communication devices, and which operation system can comprise one or more computing systems.

As used herein, with respect to any aforementioned and below mentioned uses, the term “in response to” can refer to any one or more states including, but not limited to: at the same time as, at least partially in parallel with, at least partially subsequent to and/or fully subsequent to, where suitable.

As used herein, the term “power” can refer to electrical and/or other source of power available to the operation system.

As used herein, the term “resource” can refer to power, money, memory, CPU bandwidth, processing power, labor, hardware, and/or software.

As used herein, the term “set” can refer to one or more.

### EXAMPLE ARCHITECTURES

One or more embodiments are now described with reference to the drawings, where like referenced numerals are used to refer to like elements throughout. In the following description, for purposes of explanation, numerous specific details are set forth to provide a more thorough understanding of the one or more embodiments. It is evident, however, in various cases, that the one or more embodiments can be practiced without these specific details.

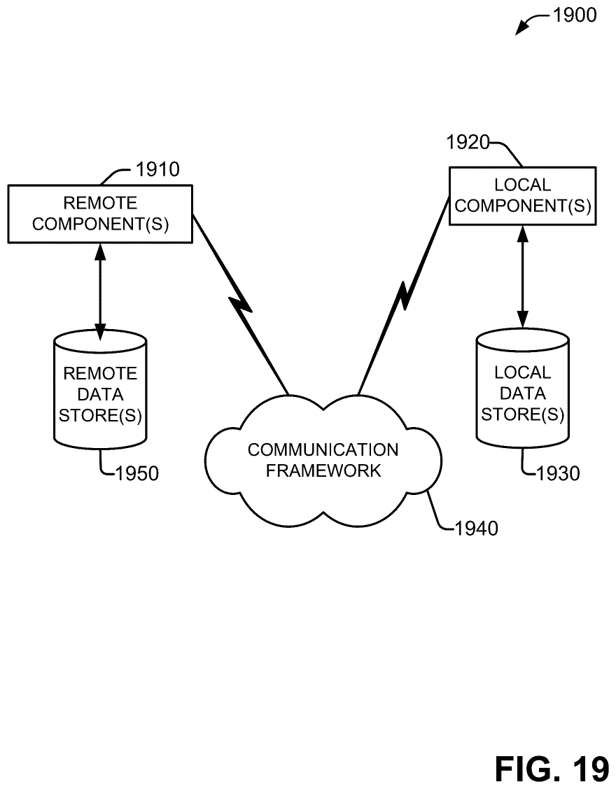

Further, the embodiments depicted in one or more figures described herein are for illustration only, and as such, the architecture of embodiments is not limited to the systems, devices and/or components depicted therein, nor to any order, connection and/or coupling of systems, devices and/or components depicted therein. For example, in one or more embodiments, the non-limiting system architectures described, and/or systems thereof, can further comprise one or more computer and/or computing-based elements described herein with reference to an operating environment, such as the operating environment 1900 illustrated at FIG. 19. In one or more described embodiments, computer and/or computing-based elements can be used in connection with implementing one or more of the systems, devices, components, and/or computer-implemented operations shown and/or described in connection with FIGS. 1-18 and/or with other figures described herein.

Turning now in particular to one or more figures, and first to FIG. 1, illustrated is a block diagram of an example, non-limiting acoustic resonator device 100, such as a sealed cavity bulk acoustic wave resonator (S-BAR) that can comprise a smooth suspended silicon membrane, controllable membrane thickness, freely definable cavity shape, and/or self-formed acoustic wave confinement steps.

Generally, an S-BAR 100 can comprise an intrinsic Si thin film 106 above a cavity 108 with a self-formed deep step 110 to define the S-BAR's resonance boundary 118, which can avoid patterning piezoelectric thin film 116 and/or building reflection frames to confine acoustic wave energy. The piezoelectric material 116 can be disposed above the probing or bumping pads 110 to facilitate testing and integration with other devices of a system (e.g., electromechanical system).

As illustrated at FIG. 1, showing a cross-section of the S-BAR 100, a sealed cavity (e.g., an air cavity) 108 can be provided fully sealed within a silicon element 102. The silicon element 102 can comprise an initial silicon layer 104, which would be fabricated at and/or employed at a substrate (e.g., a substrate 202 of a silicon-on-insulator wafer), and a silicon membrane 106 formed to be unitary (e.g., a single continuous and/or contiguous body) with the silicon layer 104. The formation of the silicon membrane 106 seals the sealed cavity 108.

As illustrated, each of the silicon membrane 106 and the silicon layer 104 can form a boundary and/or define at least a portion of the sealed cavity 108. The silicon membrane 108 can comprise at least a cavity-facing or cavity-defining, internal surface 1061 and an external surface 106E facing outwardly from the sealed cavity 108.

At the external surface 106E, a multi-layer film 113 is disposed. The multi-layer film 113 can comprise at least a bottom electrode 114 and a piezoelectric layer 116.

The bottom electrode 114 can be disposed at the external surface 106E and at a top surface 102T of the silicon element 102. The bottom electrode 114 can therefore cover at least a portion of total top surfaces of the silicon element 102. In one or more embodiments, the bottom electrode 114 does not fully cover the silicon element 102, as illustrated at the left side of the S-BAR 100 of FIG. 1.

The piezoelectric layer 116 can be disposed atop the bottom electrode 114. That is, the piezoelectric layer 116 is spaced from the silicon membrane 106 by the bottom electrode 114. In one or more embodiments, at least a portion of the piezoelectric layer 116 can be disposed at one or more top surfaces 102T of the silicon element 102, such as where the bottom electrode 114 does not cover the silicon element 102 (e.g., at section 115 at the left side of the illustrated S-BAR device 100 at FIG. 1).

Due to one or more manufacturing/fabrication steps for forming the S-BAR 100, to be discussed below in detail, one or more bumping pads 110 (e.g., steps 110) can be defined by at least a raised portion of the silicon element 102 (e.g., of the silicon layer 104) adjacent to and/or surrounding the sealed cavity 108 and/or silicon membrane 106. As illustrated at FIG. 1, a bumping pad 110 can comprise an upper surface 110T disposed at a greater distance from the base surface 104B of the silicon layer than the external (e.g., outer) surface 106E of the silicon membrane.

The multi-layer film 113 further can comprise a second electrode 120 disposed atop the piezoelectric layer 116. Therefore, the bottom electrode 114 and the top electrode 120 can comprise and/or be a pair of electrodes. The pair of electrodes 120, 114, such as both comprising metal, can be spaced apart from one another by the piezoelectric material (e.g., piezoelectric layer 116) disposed therebetween. The top electrode 120 can be of a same and/or different material than the bottom electrode 114. The top electrode 120 can cover at least a portion of a top surface 116T of the piezoelectric layer 116. In one or more embodiments, the top electrode 120 can cover less than all of the top surface 116T of the piezoelectric layer 116.

In one or more embodiments, the top electrode 120 and the bottom electrode 114 can be non-overlapping. Such non-overlapping portions can be spaced apart from one another in a direction along the silicon layer 104. See, for example, the region 115 as compared to the region 117 of the device 100 of FIG. 1. That is, the above-mentioned region 115 that lacks the bottom electrode 114 can be at least partially covered (indirectly due to the piezoelectric layer 116 between the step 110 and the top electrode 120) by the top electrode 120. Likewise, the above-mentioned region 17 that lacks the top electrode 120 can be at least partially covered by the bottom electrode 114.

A self-formed acoustic boundary 118 can be formed at an end portion of a step 110, such as comprising a portion of each of at least one electrode 120, 114, the piezoelectric layer 116, and the step 110. As used herein, the term “self-formed” can refer to formation based on use of manufacturing steps not directly provided for forming the acoustic boundary, to be described below in greater detail. This self-formation can avoid patterning piezoelectric thin film 116 and/or building reflection frames to confine acoustic wave energy.

In one or more embodiments, a hole or depression 121 can be formed, such as etched, into at least a portion of a thickness of the multi-layer film 113. The hole or depression 121 can allow for insertion of a via 122 or other element into one or more layers of the S-BAR 100.

In one or more embodiments, a hole or depression 121 can be formed, such as etched, through multiple layers of the device 100 allowing for access of a probe into the sealed cavity 108.

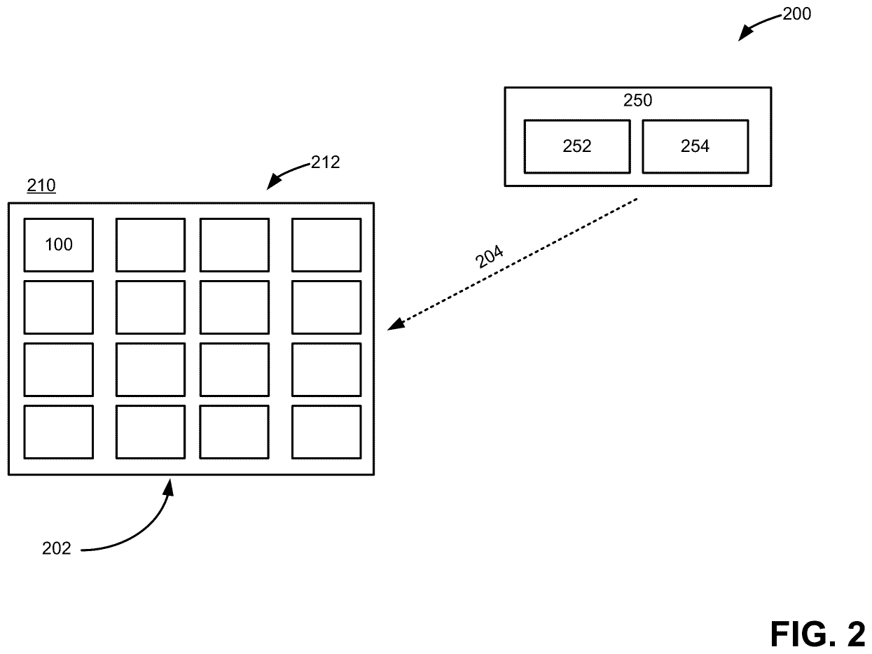

Turning next to FIG. 2, illustrated is a non-limiting system 200 comprising an acoustic resonator fabrication system 202 that can function to generally fabricate an S-BAR device 100 and/or a batch 210 comprising a plurality of S-BAR devices 100. The batch 210 can be formed at a common substrate 202 based on a common silicon-on-wafer (SOI) platform.

The non-limiting system 200 further can comprise a fabrication system 250 comprising one fabrication devices 252 controlled by one or more processors 254.

Generally, the fabrication system 250 can comprise any suitable computing devices, hardware, software, operating systems, drivers, network interfaces and/or so forth. A bus 105 can communicatively, electrically, operatively, optically and/or otherwise operatively couple a processor 254 and one or more fabrication devices 252.

Communication among the components of the fabrication system 250 can be by any suitable method. Communication can be facilitated by wired and/or wireless methods including, but not limited to, employing a cellular network, a WAN (e.g., the Internet), and/or a LAN. Suitable wired or wireless technologies for facilitating the communications can include, without being limited to, Wi-Fi, GSM, UMTS, WiMAX, enhanced GPRS, 3GPPLTE, 3GPP2UMB, HSPA, ZIGBEE® and other 802.XX wireless technologies and/or legacy telecommunication technologies, BLUETOOTH®, SIP, RF4CE protocol, WirelessHART protocol, 6LoWPAN, Z-Wave, an ANT protocol, a UWB standard/protocol and/or other proprietary and/or non-proprietary communication protocols.

The processor 254 can be one of a plurality of processors. A processor 254 can comprise a computer processing unit, microprocessor, classical processor and/or like processor.

In one or more embodiments, the fabrication system 250 can comprise a machine-readable memory that can be operably connected to a processor 254. The memory can store computer-executable instructions that, upon execution by the processor 254, can cause the processor 254 and/or one or more other components of the fabrication system 250 to perform one or more fabrication operations 204.

Using the non-limiting system 200, an S-BAR 100 can be fabricated having an intrinsic silicon substrate 102 with sealed cavity 108, bottom (e.g., Pt) electrode 114, middle piezoelectric (e.g., A10.75Sc0.25N) material 116, and top (e.g., Al) electrode 120, respectively. The membrane (e.g., silicon membrane 106) above the sealed cavity 108 can comprise crystalline silicon with tunable thickness and a processed smooth surface.

The sealed cavity 108 can have associated therewith a self-formed boundary 118 with a length of approximately 1 μm and a height 112 of approximately 600 nm, which can help suppress lateral transmission of acoustic waves to reduce acoustic loss.

Pt can provide low resistance as the bottom metal 114 and has good lattice matching with A10.75Sc0.25N. Al can be employed as the top metal 120 due to its high conductivity.

Different from an existing FBAR operating on the symmetric first-order (S1) Lamb mode, the proposed S-BAR can work on asymmetric second-order (A2) mode with K2 enhancement.

It is also noted that the first-order symmetric Lamb wave mode (S1) has been utilized in existing FBAR frameworks but is limited in operational frequency. To address this limitation, the proposed S-BAR can tune the coupled piezoelectric mutual energy, which is shown in the following equation, to excite the second-order asymmetric Lamb wave mode (A2): Uₘ=¼ RV (T dE+EdT) dV, where Uₘ is the piezoelectric mutual energy which determines the K2, V is the volume of the piezoelectric layer, T is the stress tensor, and E is the electric intensity vector. Based on the stress distribution in an existing FBAR structure, symmetrical Lamb wave odd order modes (S1, 3, 5 . . . ) have nonzero Uₘ, while the asymmetrical Lamb wave even order modes (A2, 4, 6 . . . ) feature zero Um. To achieve nonzero Um for the even order modes, S-BAR utilizes the intrinsic Si thin film, which features low mechanical loss, to tune the stress distribution of the even order mode in the piezoelectric film/volume.

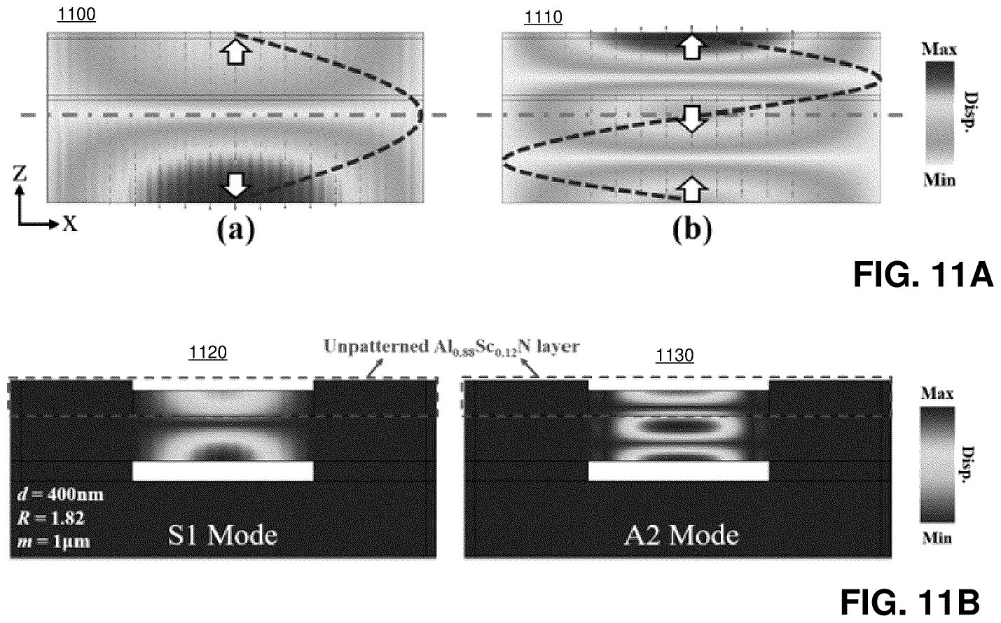

FIG. 11A shows the S1 and A2 mode displacement distributions and stress fields of the proposed S-BAR based on finite-element analysis (FEA). Graph 1100 shows the displacement mode shape of the first-order symmetric (S1) wave mode excited in the S-Bar, and graph 1110 shows the displacement mode shapes of the second-order asymmetric (A2) Lamb wave mode excited in the S-BAR. The simulated displacement mode shapes of S1 and A2 modes demonstrate that the S-BAR platform can excite odd and even modes simultaneously, as predicted by the theory. The operational frequency of the Lamb wave mode is determined by the phase velocity, order number, and thickness of the suspended film. In the same thick film, the higher the order, the higher the frequency is, which is a linear relationship without considering the effect of electrodes. In other words, the proposed S-BAR working at A2 mode will have a higher operational frequency than FBAR working at S1 mode with the same thick suspended film.

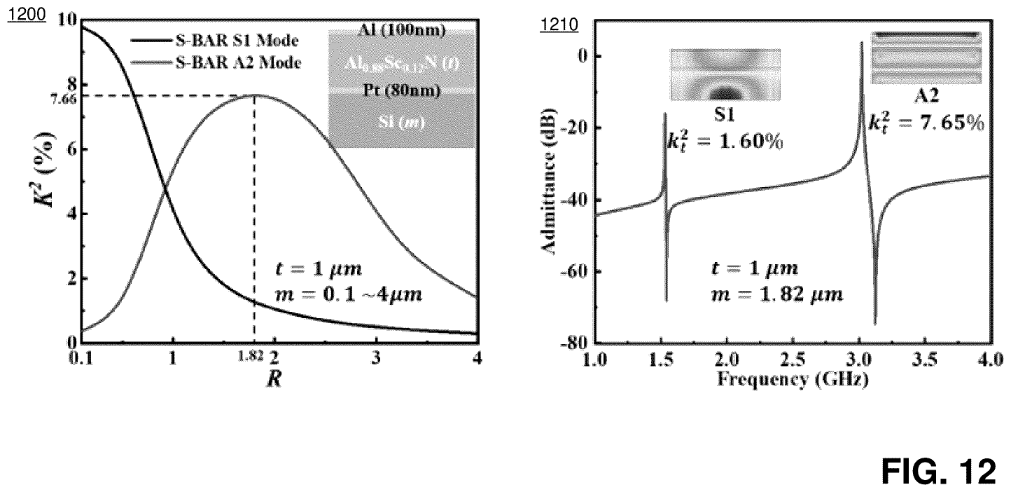

In addition to the excitation, the K² of these modes was also investigated for enhancement. As shown at FIG. 12, graph 1200, for the specified thickness of a piezoelectric layer 116 of Al_{0.88}Sc_{0.12}N (1 μm), the variation of the thickness ratio (R=m/t) leads to different changes in S1 and A2 modes. The K2 of S-BAR's SI mode keeps decreasing with the increase of R. Different from the S1 mode, with the increase of R, the zero stress node of A2 mode moves from the median plane of the Al_{0.88}Sc_{0.12}N film to the interface between A10.88Sc0.12N and Si, leading to the enhancement of K² with a maximum value of 7.66% until the zero stress node reaches the interface when R is equal to 1.82. With the further increase of R, the Um will be decreased as the zero node of A2 mode continually moves into the Si film, leading to the decrease of K².

Graph 1210 at FIG. 12 shows a designed S-BAR's (R=1.82) admittance response with S1 and A2 modes' kₜ² of 1.60% and 7.65%. With the help of intrinsic Si thin film (e.g., silicon membrane 106) in tuning stress distribution, S-BAR can excite acoustic wave modes in different frequency ranges with large K² for various applications.

Another benefit of S-BAR is the self-formed acoustic boundary 118 in sealing the cavity 108. As the FEA simulated displacement mode shapes shown in FIG. 11B illustrate, the 400-nm-thick step/frame works with the sealed cavity can well confine the acoustic wave energy without patterning the Al_{0.88}SC_{0.12}N layer 116. The S-BAR thus targets the step height (d) (element 112 at FIG. 1) at about 400 nm in an example fabrication.

### Example Fabrication Method

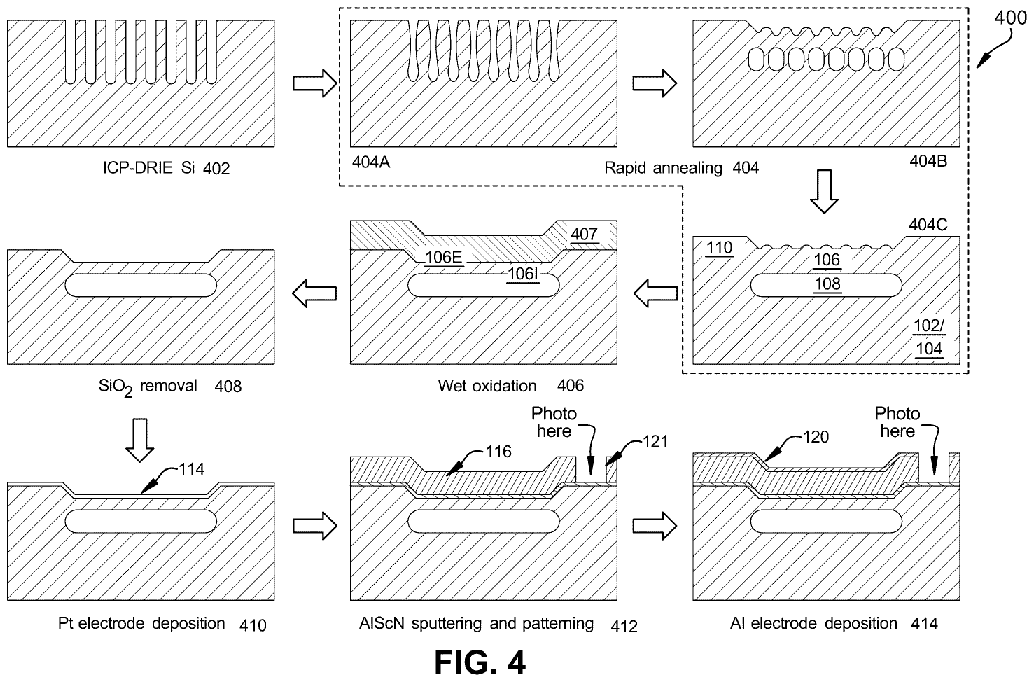

Turning now to FIG. 4, various fabrication operations 204 that can be performed by the non-limiting system 200 (e.g., the fabrication system 250) will be detailed, which can lead to formation of one or more S-BAR devices 100 having one or more same parameters, one or more different parameters, or a combination of same and different parameters (e.g., same silicon membrane thickness but different sealed cavity volume). It is noted that such same and/or different parameters can be fabricated in parallel with one another at a common substrate 202 and/or using a common SOI wafer platform.

An example fabrication process flow chart is illustrated at 400 of FIG. 4.

First, a 4-inch intrinsic (100) silicon wafer is photolithographically processed, such as using an ASML PAS5000 Stepper. See, for example the wafer 320 at FIG. 3 having a well array 322. In one or more embodiments, a suitable photolithography pattern (e.g., well array 322) can be a defined-boundary rectangular array of circular holes with a diameter of 600 nm and a spacing of 500 nm.

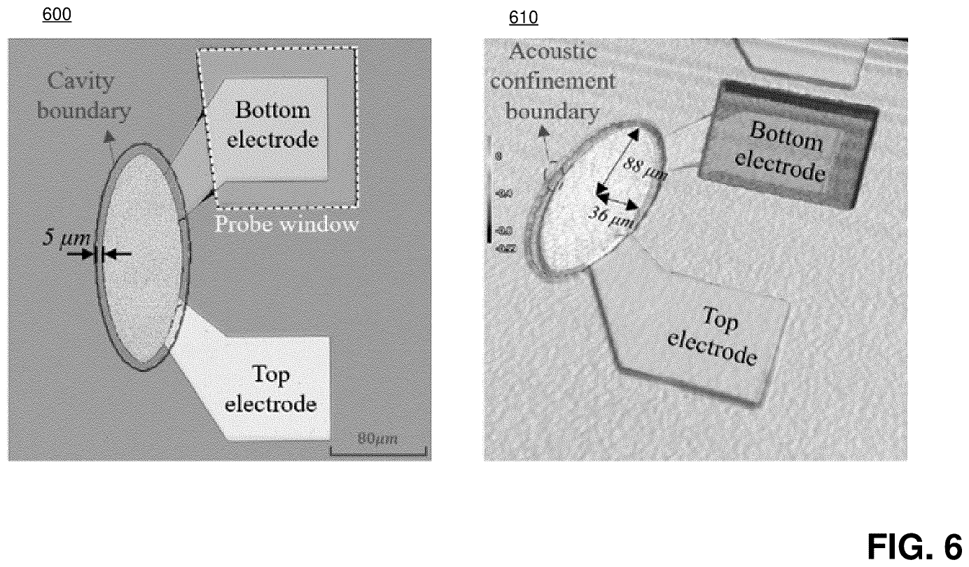

A corresponding step is to define the etched well array in the intrinsic Si wafer. The depth, diameter, and well spacing of the well array can determine the depth of the sealed cavity and the thickness of the suspended Si film. Based on the designs in the previous section, a 4.8-μm-deep well array with a diameter of 600 nm and a well spacing of 500 nm is optimized for the targeted dimensions of the suspended film and is fabricated through deep reactive ion etching (DRIE) shown in illustration 500 of FIG. 6.

Then, at step 402, the wafer is etched by ICP-DRIE. The etching depth of a 600 nm-diameter hole can be around 5 μm.

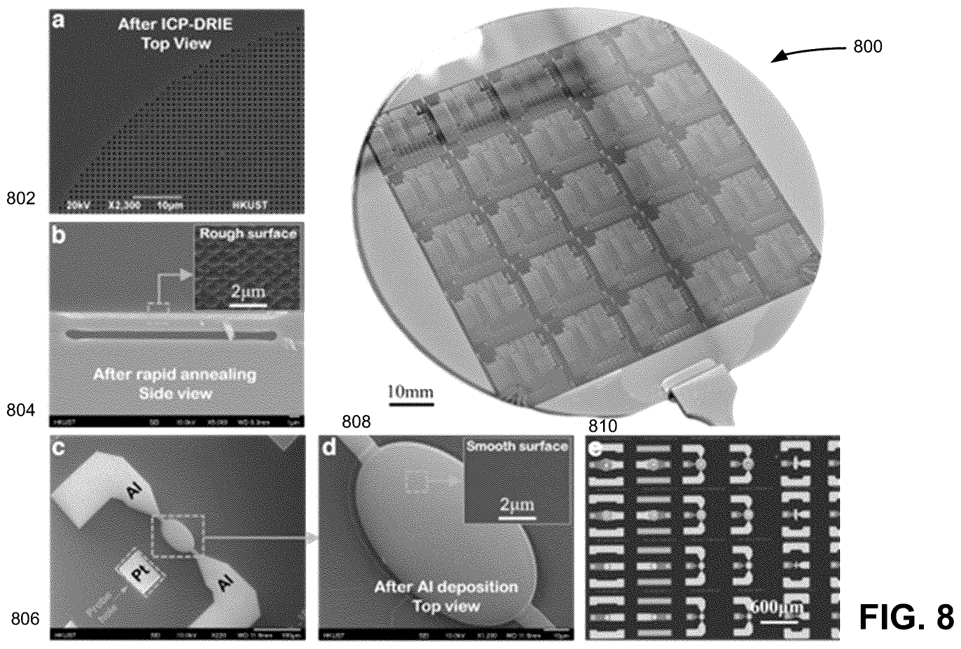

Turning briefly to FIG. 8, while also still referring to FIG. 4 throughout, illustrated are scanning electron microscope (SEM) images of the fabricated wafer after different steps. The holes array (e.g., well array 322) is formed after ICP-DRIE (step 402) with free defined boundary (e.g., ellipse, pentagon) as illustrated at illustration 802 of FIG. 8.

At step 404, including sub-steps 404A to 404C, rapid annealing can be employed, such as at 1150° C. for 100s in Argon at one atmosphere (1 atm) of pressure. During the rapid annealing process, silicon atoms of the silicon element 102 can migrate in the directions that minimize the surface energy. The well array 322 structure on the surface of the silicon wafer can gradually evolve into a sealed cavity 108 (at step 404C) with a suspended crystalline silicon membrane 106.

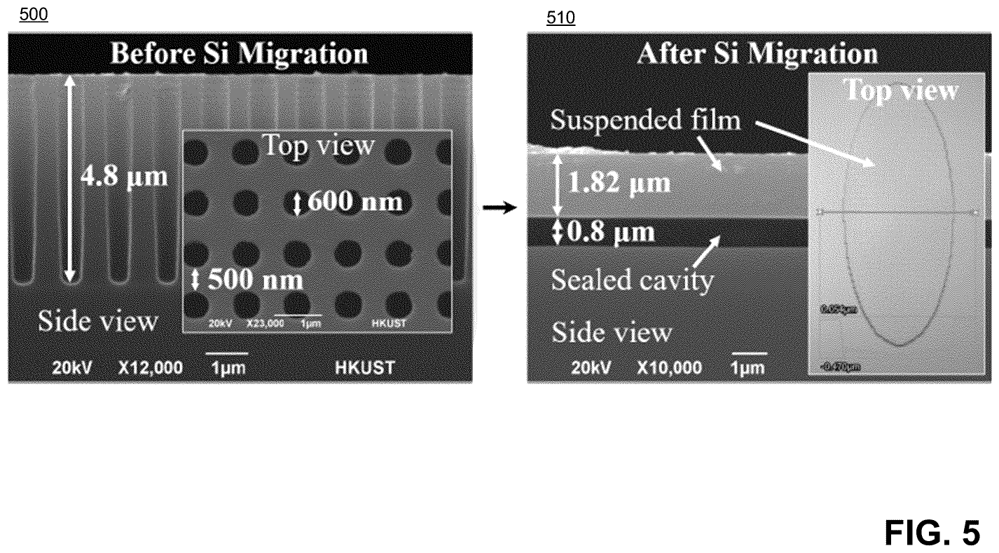

That is, in an example embodiment, the annealing (under the example condition: 1150° C., normal pressure for 110 s in Argon ambient) for the etched wafer can lead to the migration of silicon atoms for the formation of the sealed cavities with a 1.82-μm-thick suspended Si thin film. See, e.g., illustration 510 at FIG. 5.

It is worth noting that the migration of Si atoms also leads to the formation of deep steps 110 around the sides of the cavity 108, avoiding the extra steps to build acoustic energy reflection frames.

For another example, in an example embodiment, after rapid annealing, an around 0.8 μm-high sealed cavity 108 with a 1.1 μm-thick suspended membrane 106 can be achieved as shown at illustration 804 of FIG. 8. A 600 nm high and 1 μm wide step-like (e.g., step 110) transition boundary 118 can be formed at the edge of the holes array at step 404. The top surface (e.g., external surface 106E) of cavity 108 is rough after annealing, as illustrated at sub-step 404C.

At step 406, a surface smoothing can be achieved through a wet oxidation process, which can also adjust the thickness of the silicon membrane 106 to a specified value, allowing for customization of the silicon membrane 106 and device 100. This results in the smooth external surface 106E and/or internal surface 106I.

For example, in an example embodiment, turning briefly to FIG. 7, as illustrated at depictions 702, 706 and 710, AFM measurement results show that the root mean square (RMS) roughness of the suspended membrane 106 manufactured after step 404 can be about 13.1 nm, and the RMS of the un-patterned region also can reach about 3 nm. Differently, relative to existing frameworks, the RMS of cavity surface is at most approximately 10 nm to 15 nm after an annealing process. An uneven surface will affect the quality of subsequently deposited metals 114 and piezoelectric materials 116, thereby affecting device performance.

To address this issue, the one or more embodiments described herein instead employ the wet oxidation process to smooth the sealed silicon cavity wafer. In one example, oxidation furnace was set at 1050° C. and 1 atm of pressure. Since wet oxidation is isotropic, the nanometer-scale uneven silicon surface can be completely oxidized over time, and a flat SiO₂/Si interface will gradually form. Also, due to the high temperature of the oxidation process, the diffusion rate of silicon atoms is high. The migration of silicon atoms will eventually form a flat surface after a long time. As oxidation proceeds, silicon is consumed, and the thickness of the silicon membrane can be reduced. The thickness ratio of consumed silicon and formed silicon dioxide is approximately 0.44 to 130, and an oxide layer of approximately 1 μm results in approximately 131 minutes of oxidation time under experiments in a clean room. Therefore, the oxidation time can control the thickness of the remaining silicon membrane for different product specifications. Moreover, this step is also compatible with the local oxidation of silicon (LOCOS) process, and therefore it can be possible to realize silicon membranes of different thicknesses on the same wafer.

At depictions 704, 708 and 712 of FIG. 7, illustrated are AFM results of the same sealed silicon cavity wafer after a 131-minute wet oxidation process. The RMS inside cavity area (e.g., internal surface 106I within the sealed cavity 108) decreases from 13.1 to 1.5 nm, and the RMS outside cavity area (e.g., external surface 106E of the silicon membrane 106) decreases from 3.6 to 0.2 nm, respectively.

Turning briefly to FIG. 8, a fabricated S-BAR device overview is shown at illustration 806 and a zoom-in image is shown at illustration 808. Benefiting from effective smoothing, a flat surface 106E can be observed on the top of the device region.

Referring again to FIG. 4, at step 408, the oxide layer 407 can be removed by wet etching, such as using a buffered oxide etchant (BOE).

At step 410, the bottom electrode 114, such as of Pt, can be evaporatively deposited on the wafer (e.g., on the external surface 106E), followed by a lift-off process.

At step 412, a piezoelectric element 116, such as Al_{0.75}Sc_{0.25}N, can sputtered on the wafer (e.g., at the bottom electrode 114).

Also at step 412, the opening of one or more probe holes 121, such as at the steps 110, can be achieved by etching the piezoelectric material 116 (e.g., Al_{0.75}Sc_{0.25}N), such as with 86% phosphoric acid at 80° C.

At step 414, the top electrode 120, such as comprising Al, can be deposited and patterned on the wafer (e.g., atop the piezoelectric element 116).

For example, turning briefly to FIG. 6, after building the sealed cavities 108, the bottom electrodes 114 are defined based on 80-nm-thick Pt, and a piezoelectric layer 116 of 1-μm-thick Al_{0.88}Sc_{0.12}N is sputtered on the wafer followed by 100 nm top Al electrode 120 deposition. For device measurement, a probe window 121 for the bottom electrode 114 can be built by the ICP-RIE method. Illustrations 600 and 610 at FIG. 6 show an optical microscope image and a three-dimensional laser image of the fabricated S-BAR, respectively.

As a result of the fabrication process 400, a die photo at illustration 810 of FIG. 8 shows the devices' cavity area has good uniformity and high yield. The shapes of the cavities 108 can be freely defined and fabricated as any pattern (e.g., ellipse, polygon).

For example, illustration 800 at FIG. 8 shows a fabricated 4-inch wafer with a 5×5 array die distribution. Except for the dies at the four corners, the remaining 21 dies are available, which shows the stability of the fabrication for fabrication of a batch 210 of devices 100.

Referring again briefly to FIG. 2 and still to FIG. 4, it is appreciated that a plurality (e.g., a batch 210) of devices 100 can be fabricated in parallel with one another.

In one or more embodiments, for each of the acoustic wave resonators of a batch 210, a thickness of a lower portion of the silicon layer 104, disposed between the cavity 108 and the common silicon-on-insulator wafer platform 234, can have a first thickness, in a direction outward from the common silicon-on-insulator wafer platform 234, that is greater than a thickness of the silicon membrane 106 in the direction.

In one or more embodiments, for each of the acoustic wave resonators 100 of a batch 210, an external surface 106E of the silicon membrane 106, at which the multi-layer film 113 is disposed, can be disposed closer to the common silicon-on-insulator wafer platform 234 than upper portions (e.g., steps 110) of the silicon layer 104 disposed adjacent to the silicon membrane 106 and the cavity 102.

In one or more embodiments, for each of the acoustic wave resonators 100 of a batch 210, an external surface 106E of the silicon membrane 106, at which the multi-layer film 113 is disposed, can have a root mean square roughness of less than 0.5 nm, and an internal surface 106I of the silicon membrane 106, defining at least a portion of the cavity 108, can have a root mean square roughness of less than 3.0 nm.

In one or more embodiments, different ones of the acoustic wave resonators 100 of a batch 210 can comprise sealed cavities 108 with different sealed cavity volumes. That is, the sealed cavities 108 of the batch 210 can comprise a first set of sealed cavities 108 each having a first volume within a first volume range corresponding to a first set of dimensions of first well arrays 322 of first silicon wafers 320 from which the first set of sealed cavities 108 were formed, and a second set of sealed cavities 108 each having a second volume within a second volume range, different from the first volume range, corresponding to a second set of dimensions, different from the first set of dimensions, of second well arrays 322 of second silicon wafers 320 from which the second set of sealed cavities 108 were formed.

In one or more embodiments, different ones of the acoustic wave resonators 100 of the batch 210 can comprise different silicon membranes 106 with different thicknesses, the different thicknesses extending in a direction outward from the common silicon-on-insulator wafer platform 234. The different silicon membranes 106 of the batch 210 can comprise a first set of silicon membranes 106 each having a first thickness within a first thickness range corresponding to a first time range over which a wet oxidation process was applied to the first set of silicon membranes 106, and a second set of silicon membranes 106 each having a second thickness within a second thickness range, different from the first thickness range, corresponding to a second time range, different from the first time range, over which the wet oxidation process was applied to the second set of silicon membranes 106.

Any two or more of the above embodiments can be employed in parallel with one another during a same fabrication process at a common SOI platform 234 and/or at different SOI platforms 234.

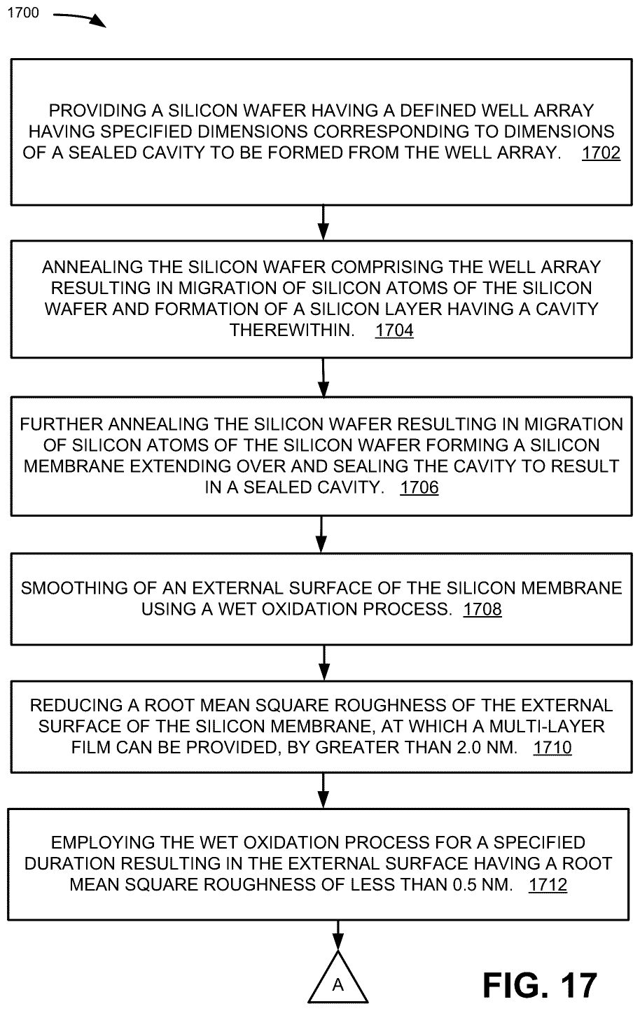

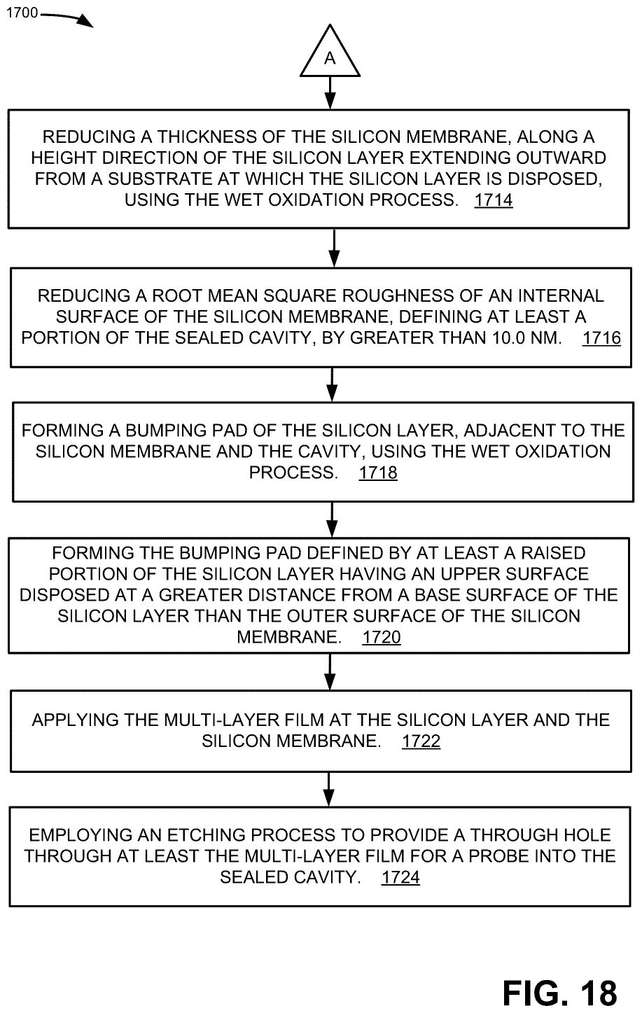

As a summary of the above description provided relative to FIGS. 1-16, and particularly of the fabrication method 400, turning now to FIGS. 17 and 18, an example process flow 1700 can comprise a set of operations for fabricating a sealed cavity bulk acoustic wave resonator (S-BAR), such as the device 100. One or more elements, objects and/or components referenced in the process flow 1700 can be those of FIGS. 1-16. Repetitive description of like elements and/or processes employed in previously described embodiments is omitted for sake of brevity.

At operation 1702, the process flow 1700 can comprise providing (e.g., by the fabrication system 250) a silicon wafer (e.g., silicon wafer 320) having a defined well array (e.g., well array 322) having specified dimensions corresponding to dimensions of a sealed cavity to be formed from the well array.

At operation 1704, the process flow 1700 can comprise annealing (e.g., by the fabrication system 250) the silicon wafer comprising the well array resulting in migration of silicon atoms of the silicon wafer and formation of a silicon layer (e.g., silicon layer 104) having a cavity (e.g., cavity 108) therewithin.

At operation 1706, the process flow 1700 can comprise further annealing (e.g., by the fabrication system 250) the silicon wafer resulting in migration of silicon atoms of the silicon wafer forming a silicon membrane (e.g., silicon membrane 106) extending over and sealing the cavity to result in a sealed cavity (e.g., sealed cavity 108).

At operation 1708, the process flow 1700 can comprise smoothing (e.g., by the fabrication system 250) of an external surface (e.g., external surface 106E) of the silicon membrane using a wet oxidation process.

At operation 1710, the process flow 1700 can comprise reducing (e.g., by the fabrication system 250) a root mean square roughness of the external surface of the silicon membrane, at which a multi-layer film (e.g., multi-layer film 113) can be provided, by greater than 2.0 nm.

At operation 1712, the process flow 1700 can comprise employing (e.g., by the fabrication system 250) the wet oxidation process for a specified duration resulting in the external surface having a root mean square roughness of less than 0.5 nm.

At operation 1714, the process flow 1700 can comprise reducing (e.g., by the fabrication system 250) a thickness of the silicon membrane, along a height direction of the silicon layer extending outward from a substrate (e.g., substrate 202 at base surface 104B) at which the silicon layer is disposed, using the wet oxidation process.

At operation 1716, the process flow 1700 can comprise reducing (e.g., by the fabrication system 250) a root mean square roughness of an internal surface (e.g., internal surface 1061) of the silicon membrane, defining at least a portion of the sealed cavity, by greater than 10.0 nm.

At operation 1718, the process flow 1700 can comprise forming (e.g., by the fabrication system 250) a bumping pad (e.g., bumping pad 110) of the silicon layer, adjacent to the silicon membrane and the cavity, using the wet oxidation process.

At operation 1720, the process flow 1700 can comprise forming (e.g., by the fabrication system 250) the bumping pad defined by at least a raised portion of the silicon layer having an upper surface (e.g., upper surface 110T) disposed at a greater distance from a base surface (e.g., base surface 104B) of the silicon layer than the outer surface of the silicon membrane.

At operation 1722, the process flow 1700 can comprise applying (e.g., by the fabrication system 250) the multi-layer film at the silicon layer and the silicon membrane.

At operation 1724, the process flow 1700 can comprise employing (e.g., by the fabrication system 250) an etching process to provide a through hole (e.g., through hole 121) through at least the multi-layer film for a probe into the sealed cavity.

### Example Measurement Results

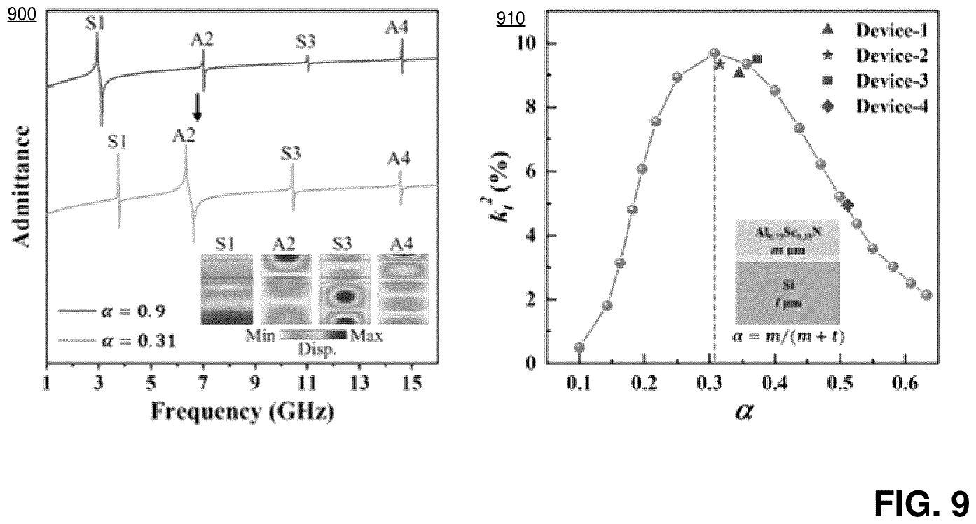

Turning next to FIGS. 9 to 16, illustrated are various graphs demonstrating various properties, effects, operations, and/or optimizations corresponding to one or more S-BAR devices 100 as described above.

First, at FIG. 9, illustrated at graph 900 are simulated admittance responses of S-BARs showing that a thickness ratios (a) of the piezoelectric Al_{0.75}Sc_{0.25}N layer thickness to the total thickness can be used to generate A2 mode. When the a is close to 1, the S1 mode of the resonator has the largest k²(kₜ²=((fₚ²−fₛ²))/(fₚ²)) among all the resonant modes, where the fₛ and fₚ are the resonance and anti-resonance frequency, respectively. When the a is close to 0.3, the A2 mode of the resonator is fully excited, having the largest kₜ².

The principle behind this is that the silicon membrane participates in tuning the stress distribution of the resonator. The optimized stress distribution can increase the coupling piezoelectric mutual energy Um for a higher order mode. Then the kₜ² can be enhanced since the Uₘ is proportional to the kₜ². The coupling piezoelectric mutual energy equation is an integral formula: Uₘ=¼ ∫ᵥ(TdE+EdT) dV, where the integral domain V is the volume of the piezoelectric Al_{0.75}Sc_{0.25}N layer, T is the stress tensor, d is the piezoelectric (strain) coefficient matrix, and E is the electric field vector. For S-BAR, neither d nor E is a function of integral domain V and can be seen as constants, only T has a distribution along the z direction. The integral of stress T in Al_{0.75}Sc_{0.25}N layer plays a role of Uₘ.

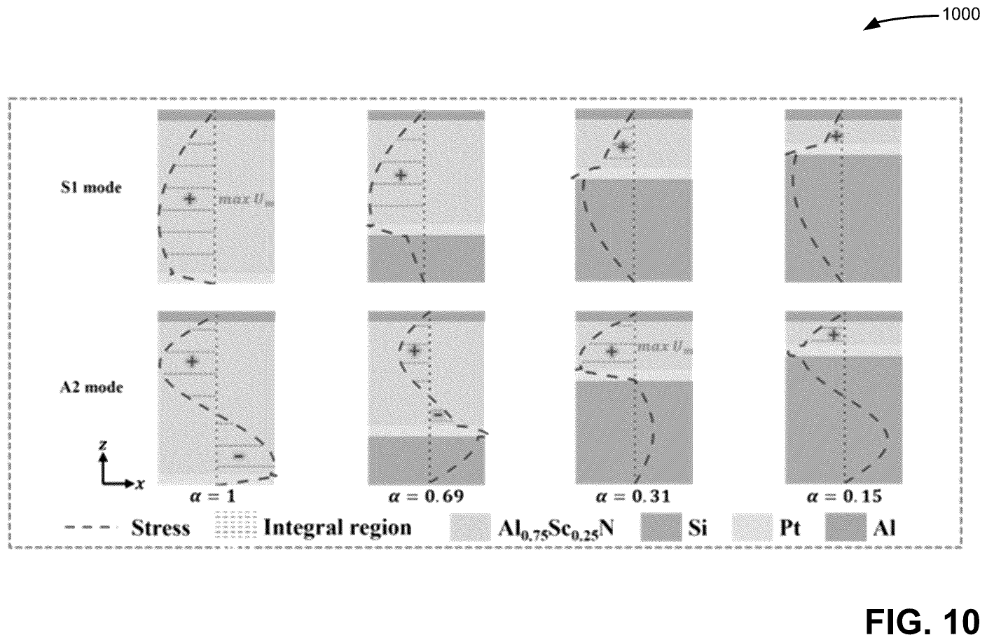

Turning to FIG. 10, the simulated stress T distributions based on finite element analysis (FEA) of S-BAR at S1 and A2 modes with different a are illustrated at graph 1000. Ignoring the sudden change at the interface of material stack, the stress distribution of S-BAR satisfies the sinusoidal form, with a period of 0.5n, where n is the order of the resonant mode. When a is equal to 1, the distribution of half-period stress makes the Uₘ of the resonator working in the S1 mode reach the maximum value. At the same time, the distribution of one-period stress makes the Uₘ of the A2 mode almost 0. As a gradually decreases, the Uₘ of the S1 mode will become smaller due to the smaller integral domain in graph 1000, but the Uₘ of the A2 mode will increase and reach a peak at around α=0.31, and then decrease. When the a decreases, the stress zero point of A2 mode moves from Al_{0.75}Sc_{0.25}N layer to the interface between the Al_{0.75}Sc_{0.25}N and silicon, which makes the integrated Uₘ increase and reach the maximum value, thus producing the maximum kₜ².

Referring again to FIG. 9, the graph 910 illustrates a verification of the above-noted conclusion relative to graph 1000 using eigenmode analysis. The A2 mode of an S-BAR can be excited and reaches the maximum kₜ² of 9.69% at α=0.31. Based on graph 910, four S-BAR wafers (e.g., listed as Device-1 through Device-4) with different a were fabricated for demonstration.

It is noted that for graph 910, four 4-inch wafers were fabricated, one of which is not smoothed (Wafer-1), two are smoothed one round (Wafer-2 and Wafer-3), and the remaining one is smoothed two rounds (Wafer-4). The thickness of the suspended silicon membrane of the four wafers is approximately 1100, 910, 910, and 850 nm, respectively. The designed different silicon membrane thickness was used to verify the correctness of the theoretical design of the kₜ² in graph 910 of FIG. 9.

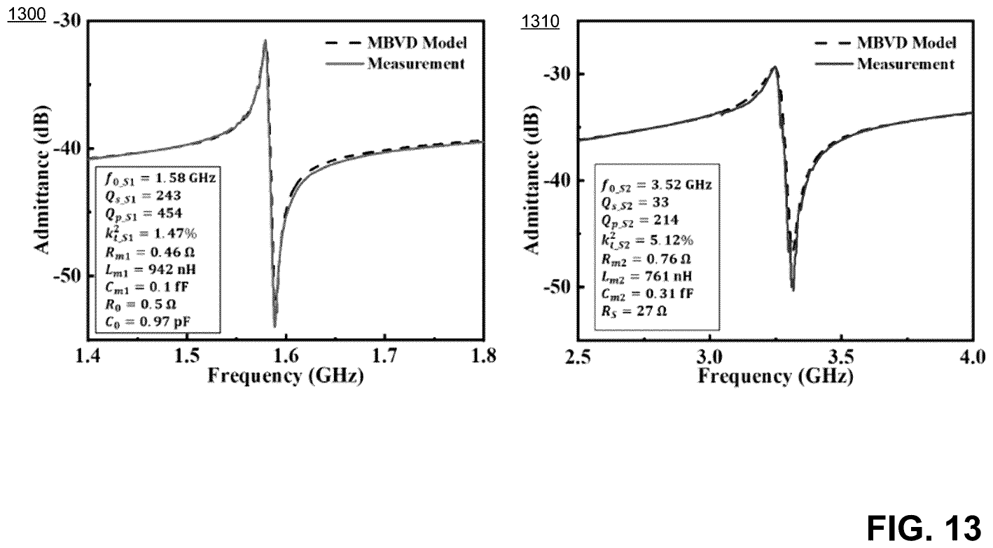

Looking now to FIG. 13, the fabricated S-BAR is characterized by a vector network analyzer in dry air at room temperature. The measured admittance responses with MBVD modeled fitting of S1 and A2 modes are illustrated at graph 1300, illustrating the S1 mode, and graph 1310, illustrating the A2 mode. The example resonant frequencies of the S1 and A2 modes are 1.58 and 3.52 GHz, respectively. The example kₜ² of S1 and A2 modes are 1.47% and 5.12%, respectively, with example quality factors Qₛ of 243 and 33, and Qₚ of 454 and 214, respectively. In general, the one or more embodiments described herein provide a unique solution for subsequent fabrication with a sturdy sealed cavity structure and high kₜ², A2 mode.

Based on the MBVD model and the measured result, the fabricated resonator features a large series resistance (Rs≈27Ω) leading to a small Qₛ. The large Rₛ can be due to the contamination of the electrodes and the poor metal coverage at the cavity boundary. Another challenge can be that the surfaces 1061 and 106E of the silicon membrane 106 formed by thermal annealing are rough, prior to wet oxidation, which can affect the crystal quality of the following Al_{0.75}Sc_{0.25}N thin film 116. This is addressed using the wet oxidation (e.g., step 406 of FIG. 4).

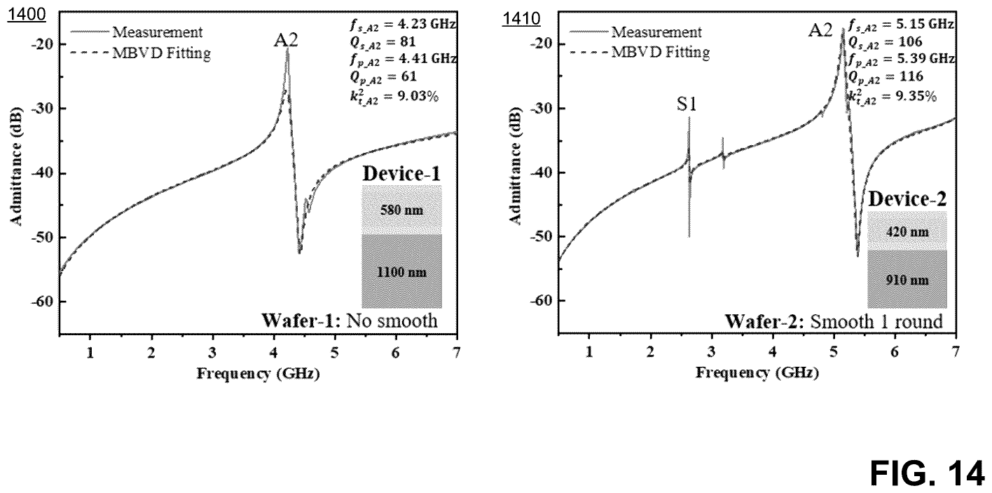

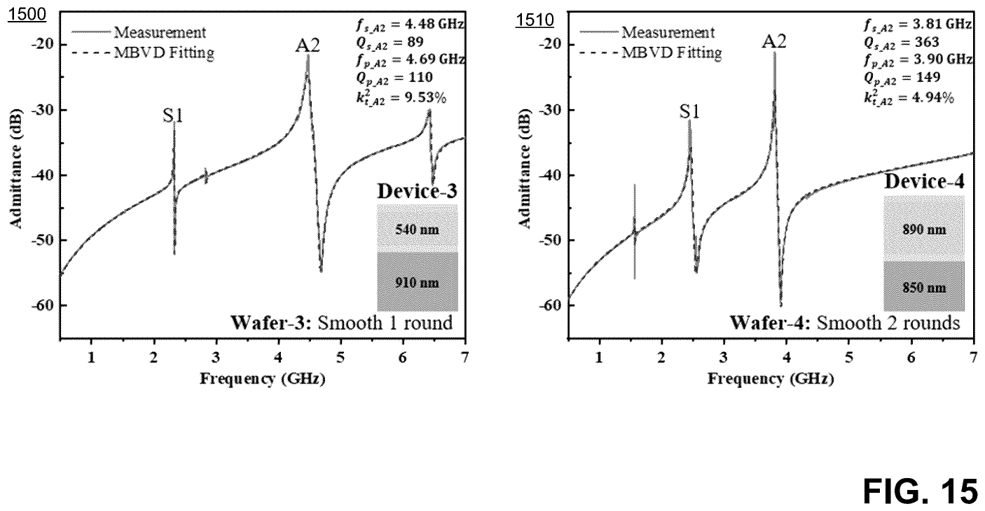

Turning now to FIGS. 14 to 16, fabricated S-BARs can be characterized by a vector network analyzer in dry air at room temperature. At FIGS. 14 and 15, and corresponding graphs 1400, 1410, 1500 and 1510, illustrated are measured admittance responses of Devices 1 to 4 of the previously discussed graph 910 of FIG. 9, with their modified Butterworth-Van Dyke (MBVD) modeled fitting curves shown at the graphs 1400, 1410, 1500 and 1510.

Wafer-1 (graph 1400) has not been smoothed, and its silicon membrane thickness is around the initial 1100 nm. The target A2 mode of Device-1 fabricated on it has a kₜ² of 9.02% at a resonance frequency of approximately 4.23 GHz. Since its rough surface affects the quality of metal and Al_{0.75}Sc_{0.25}N, its 3-dB Qₛ and Qₚ are 81 and 61, respectively. Device-2 (graph 1410) and Device-3 (graph 1500) have the same silicon thickness but different Al_{0.75}Sc_{0.25}N thicknesses of 420 nm and 540 nm, respectively. Their measured admittance responses show the target A2 mode working at approximately 5.15 GHz and approximately 4.48 GHz, respectively, with kₜ² of 9.35% and 9.53%, respectively. After smoothing one round, the Q of Device-2 and Device-3 are larger than Device-1, reaching Qₛ of 106 for Device-2 and 116 for Device-3 and Qₚ of 89 for Device-2 and 110 for Device-3.

Wafer-4 (graph 1510) has been smoothed after two rounds. Device-4 on Wafer-4 achieves a Qₛ of 363 at 3.81 GHz and a Qₚ of 149 at 3.90 GHz. Due to design considerations, the thicker Al_{0.75}Sc_{0.25}N makes its α=0.51, which brings a kₜ² of 4.94%. The kₜ² of four devices are plotted with a theoretical predicted curve graph 910 (FIG. 9). The theoretical design is consistent with the experimental results.

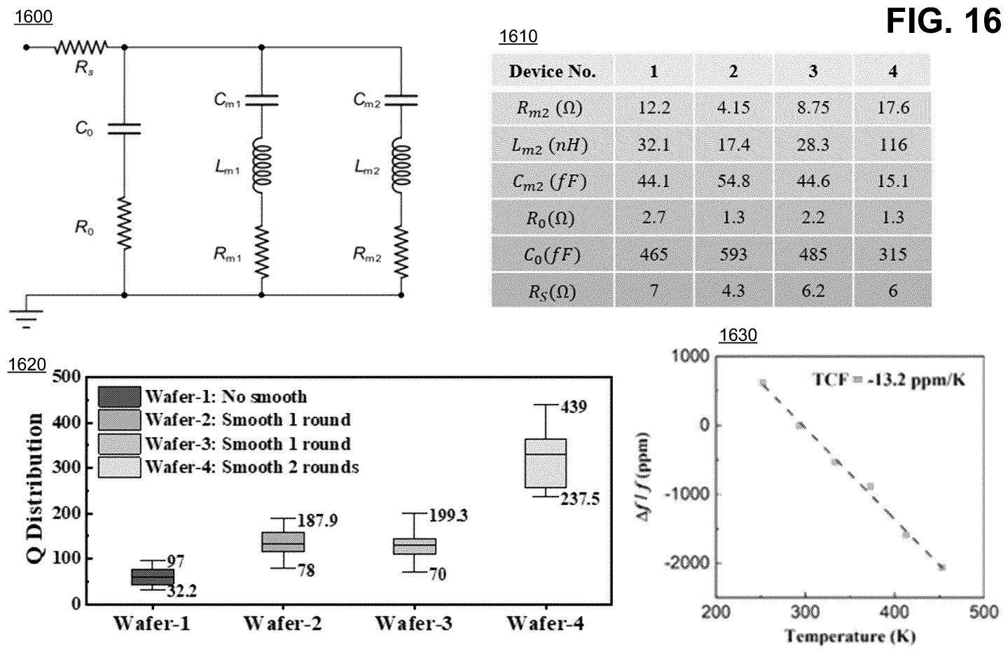

In connection therewith, illustration 1600 of FIG. 16 shows the MBVD fitting circuits of the measured four S-BARs with a key parameters table 1610. Compared with the unsmoothed Wafer-1 (graph 1400), the Ro and Rₛ of Wafers-2 through 4 (graphs 1410, 1500 and 1510, respectively) are smaller. This indicates that the deposited metal electrode on the smoothed wafers has better quality and sputtered Al_{0.75}Sc_{0.25}N has smaller dielectric loss. This can be beneficial to improving the Q of the fabricated S-BARs.

At graph 1620 of FIG. 16, the Q distribution box plot of measured S-BARs on four wafers also demonstrates that the Q of the devices are increased by the smoothing process. After two rounds of smoothing, the measured maximum Q of S-BAR increased by around 400% (e.g., from 97 to 439). The performance of S-BAR can be further improved by optimized thickness design (kₜ²) and smoothing process (Q). The TCF of the S-BAR is measured in a vacuum cryogenic probe station.

Lastly, at graph 1630 of FIG. 16, illustrated is the temperature coefficient of frequency (TCF) of Al_{0.75}Sc_{0.25}N S-BAR is-13.2 ppm/K from 253 to 453 K, which is much larger than the measured TCF (−30 ppm/K) of Al_{0.75}Sc_{0.25}N FBAR of existing frameworks. The stacked structure formed by silicon membrane and Al_{0.75}Sc_{0.25}N effectively helps to improve the TCF of S-BARs.

### BRIEF SUMMARY

As another summary of the above description provided relative to FIGS. 1-16, one or more benefits of the one or more embodiments described herein can comprise any one or more of the following.

The sealed silicon cavity (SSC) wafer features a smooth suspended silicon membrane with controllable thickness, customizable cavity shapes with high density (see, e.g., representation 308 at FIG. 3), self-forming acoustic wave confinement steps, and smaller absolute value of temperature coefficient of frequency (TCF) for acoustic resonators.

The construction of the SSC can be realized by DRIE and a rapid annealing process with low cost and simple steps.

Different from a hydrogen annealing smoothing process, a wet oxidation-based surface smoothing process for the SSC wafer can achieve a root mean square (RMS) roughness of 1.5 nm on the cavity surface (e.g., including the internal surface 1061). The flat external surface 108E can support the subsequent high-quality material film deposition. In addition, the SSC platform can be compatible with CMOS and can realize MEMS and CMOS simultaneous fabrication.

Different from an existing FBAR operating on the symmetric first-order (S1) Lamb mode, the sealed cavity bulk acoustic wave resonator (S-BAR) 100 can work on asymmetric second-order (A2) mode with Kₜ² enhancement. Based on the presented SSC platform, provided can be a high-order mode enhanced A_{10.75}SC_{0.25}N S-BAR. The measured data (e.g., FIGS. 9-16) illustrate that the fabricated S-BARs 100 can achieve a maximum quality factor (Q) of 439, a peak piezoelectric coupling coefficient (Kₜ²) of 9.85%, and a TCF of −13.2 ppm/K for asymmetric second order (A2) Lamb mode.

### ADDITIONAL SUMMARY

For simplicity of explanation, the computer-implemented methodologies and/or processes provided herein are depicted and/or described as a series of acts. The subject application is not limited by the acts illustrated and/or by the order of acts, for example acts can occur in one or more orders and/or concurrently, and with other acts not presented and described herein. The operations of process flows of the figures provided herein are example operations, and there can be one or more embodiments that implement more or fewer operations than are depicted.

Furthermore, not all illustrated acts can be utilized to implement the computer-implemented methodologies in accordance with the described subject matter. In addition, the computer-implemented methodologies could alternatively be represented as a series of interrelated states via a state diagram or events. Additionally, the computer-implemented methodologies described hereinafter and throughout this specification are capable of being stored on an article of manufacture to facilitate transporting and transferring the computer-implemented methodologies to computers. The term article of manufacture, as used herein, is intended to encompass a computer program accessible from any machine-readable device or storage media.

In summary, described is a technology that facilitates fabrication of an acoustic wave resonator 100. For instance, an acoustic wave resonator 100 can comprise a silicon layer 104 comprising a base surface 104B, a multi-layer film 113 disposed at the silicon layer 100 opposite the base surface 104B and comprising a metal electrode 114 and a piezoelectric material 116, and a cavity 108 within the silicon layer 104, wherein the cavity 108 is sealed, at a location opposite the base surface 104B, by a silicon membrane 106. The silicon layer 104 and the silicon membrane 106 can be provided as a unitary silicon element 102. In another instance, a batch 210 of the acoustic wave resonators 100 can be fabricated using a common silicon-on-insulator wafer platform 212.

Indeed, in view of the one or more embodiments described herein, a practical application of the above-indicated device, system and/or method can be an ability to provide a sealed bulk acoustic resonator (S-BAR) employing silicon migration technology (SiMiT) and wet oxidation smoothing to provide an acoustic wave resonator having a customizable cavity volume, customizable silicon thin-film thickness sealing the cavity, and optimizable quality factor, S1 mode parameters and/or A2 mode parameters. These are useful and practical applications of computers, thus providing an enhanced (e.g., improved and/or optimized) acoustic filter, transducer, and/or other application. Overall, such tools can constitute a concrete and tangible technical and/or physical improvement in the fields of medicine, healthcare, wireless communication, etc.

Furthermore, one or more embodiments described herein can be employed in a real-world system based on the disclosed teachings. For example, one or more embodiments described herein can function with a computer system to fabricate one or more such acoustic wave resonators in parallel with one another, such as having one or more different parameters.

Further, one or more embodiments described herein are inherently and/or inextricably tied to computer technology and cannot be implemented outside of a computing environment. For example, one or more processes performed by one or more embodiments described herein can more efficiently, and/or more feasibly, provide acoustic wave resonator fabrication of customizable and optimized acoustic wave resonators than can be provided by existing frameworks.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not described herein for the sake of brevity, but known by those of skill in the art.

In one or more embodiments, one or more of the processes described herein can be performed by one or more specialized computers (e.g., a specialized processing unit, a specialized classical computer, and/or another type of specialized computer) to execute defined tasks related to the one or more technologies described above. One or more embodiments described herein and/or components thereof can be employed to solve new problems that arise through advancements in technologies mentioned above, employment of cloud operation systems, computer architecture and/or another technology.

One or more embodiments described herein can be fully operational towards performing one or more other functions (e.g., fully powered on, fully executed and/or another function) while also performing the one or more operations described herein.

The paragraphs that follow provide additional summaries describing example devices, systems, and/or methods.

Generally, a wafer-level sealed silicon inter-CMOS platform for integrated microacoustic devices, can comprise a sealed silicon cavity wafer, acoustic resonators, and a surface smoothing process.

Generally, a fabrication method for a sealed silicon cavity wafer or sealed silicon cavity acoustic resonator can comprise an etching process and annealing process of the sealed silicon cavity wafer, the etching process, comprising the etching pattern being a hole array, and/or the annealing process, comprising a process temperature of 1150° C. and/or a gas ambient of Argon.

Generally, Generally, a sealed silicon cavity acoustic resonator can comprise a suspended silicon membrane above the sealed cavity, the sealed cavity having a self-formed boundary, and/or a spacing between each cavity can be smaller than 2.5 μm.

Generally, a sealed silicon cavity acoustic resonator can comprise a suspended silicon membrane comprising crystalline silicon with tunable thickness and smooth surface.

Generally, a sealed silicon cavity acoustic resonator can comprise a suspended silicon membrane having a low root mean square (RMS) roughness smaller than 1.6 nm.

Generally, a sealed silicon cavity acoustic resonator can comprise a piezoelectric material layer, and/or a single or double metal electrode layer behind or above the piezoelectric material layer.

Generally, a sealed silicon cavity acoustic resonator can comprise a piezoelectric material layer, comprising AlN or AlScN piezoelectric material.

Generally, a fabrication method for a sealed silicon cavity acoustic resonator can comprise a stress distribution tuning method, higher-order mode excitation, and/or piezoelectric coupling coefficient increasing.

The stress distribution tuning method can comprise employing a stacked structure of other materials and piezoelectric materials and/or a method for adjusting the thickness ratio of other materials to piezoelectric materials.

Generally, a fabrication method for a sealed silicon cavity acoustic resonator can comprise a surface smoothing process, comprising a silicon wet oxidation process comprising a process of wet oxidation of a silicon wafer, a process temperature of 1050° C. and/or a process pressure of 1 atm.

An example acoustic wave resonator can comprise a silicon layer comprising a base surface, a multi-layer film disposed at the silicon layer opposite the base surface and comprising a metal electrode and a piezoelectric material, and a cavity within the silicon layer, wherein the cavity is sealed, at a location opposite the base surface, by a silicon membrane.

The example acoustic wave resonator can comprise the silicon membrane and the silicon layer being of a unitary element of the acoustic wave resonator.

The example acoustic wave resonator can comprise the multi-layer film further comprising a pair of metal electrodes, comprising the metal electrode, spaced apart from one another by the piezoelectric material disposed therebetween.

The example acoustic wave resonator can comprise the pair of metal electrodes comprising non-overlapping portions that are spaced from one another in a direction along the silicon layer.

The example acoustic wave resonator can further comprise a bumping pad defined by at least a raised portion of the silicon layer, the bumping pad comprising an upper surface disposed a greater distance from the base surface than an outer surface of the silicon membrane.

The example acoustic wave resonator can comprise the multi-layer film and the sealed cavity being jointly configured to provide an S1 resonant mode between 1.0 GHz and 2.0 GHz and an A2 resonant mode greater than 3.0 GHz.

The example acoustic wave resonator can comprise the multi-layer film disposed at an external surface of the silicon membrane and the external surface having a root mean square roughness of less than 0.5 nm.

The example acoustic wave resonator can comprise the acoustic wave resonator being one of a group of acoustic wave resonators fabricated at a silicon-on-insulator wafer platform. The respective acoustic wave resonators of the group of acoustic wave resonators can be fabricated to comprise respective controlled thickness ranges of respective silicon membranes of the respective acoustic wave resonators.

An example batch of acoustic wave resonators can be fabricated using a common silicon-on-insulator wafer platform. Each of the acoustic wave resonators can comprise a silicon body disposed at the common silicon-on-insulator wafer platform and comprising a silicon layer adjacent the common silicon-on-insulator wafer platform, a cavity defined within the silicon layer, and a silicon membrane sealing the cavity. The silicon layer and the silicon membrane can be provided as a unitary silicon element. A multi-layer film can be disposed at the silicon membrane opposite the common silicon-on-insulator wafer platform and can comprise a pair of metal electrodes separated by a piezoelectric material.

The example batch of acoustic wave resonators can comprise each of the acoustic wave resonators having a thickness of a lower portion of the silicon layer, disposed between the cavity and the common silicon-on-insulator wafer platform, has a first thickness, in a direction outward from the common silicon-on-insulator wafer platform, that is greater than a thickness of the silicon membrane in the direction.

The example batch of acoustic wave resonators can comprise each of the acoustic wave resonators having an external surface of the silicon membrane, at which the multi-layer film is disposed, is disposed closer to the common silicon-on-insulator wafer platform than upper portions of the silicon layer disposed adjacent to the silicon membrane and the cavity.

The example batch of acoustic wave resonators can comprise each of the acoustic wave resonators having an external surface of the silicon membrane, at which the multi-layer film is disposed, has a root mean square roughness of less than 0.5 nm, and an internal surface of the silicon membrane, defining at least a portion of the cavity, has a root mean square roughness of less than 3.0 nm.

The example batch of acoustic wave resonators can comprise different ones of the acoustic wave resonators of the batch of acoustic wave resonators comprising sealed cavities with different sealed cavity volumes. The sealed cavities can comprise a first set of sealed cavities each having a first volume within a first volume range corresponding to a first set of dimensions of first well arrays of first silicon wafers from which the first set of sealed cavities were formed, and a second set of sealed cavities each having a second volume within a second volume range, different from the first volume range, corresponding to a second set of dimensions, different from the first set of dimensions, of second well arrays of second silicon wafers from which the second set of sealed cavities were formed.

The example batch of acoustic wave resonators can comprise different ones of the acoustic wave resonators of the batch of acoustic wave resonators comprising different silicon membranes with different thicknesses, the different thicknesses extending in a direction outward from the common silicon-on-insulator wafer platform. The different silicon membranes can comprise a first set of silicon membranes each having a first thickness within a first thickness range corresponding to a first time range over which a wet oxidation process was applied to the first set of silicon membranes, and a second set of silicon membranes each having a second thickness within a second thickness range, different from the first thickness range, corresponding to a second time range, different from the first time range, over which the wet oxidation process was applied to the second set of silicon membranes.

An example method for fabricating an acoustic wave resonator an comprise annealing a silicon wafer comprising a well array resulting in migration of silicon atoms of the silicon wafer and formation of a silicon layer having a cavity therewithin, where the annealing the silicon wafer further results in migration of silicon atoms of the silicon wafer forming a silicon membrane extending over and sealing the cavity to result in a sealed cavity, and where dimensions of the sealed cavity correspond to specified dimensions of the well array, and applying a multi-layer film at the silicon layer and the silicon membrane.

The example method can further comprise smoothing of an external surface of the silicon membrane using a wet oxidation process.

The example method can further comprise fabricating an external surface of the silicon membrane at which the multi-layer film is disposed using the wet oxidation process, and the external surface having a root mean square roughness of less than 0.5 nm.

The example method can further comprise using the wet oxidation process comprising reducing a root mean square roughness of the external surface of the silicon membrane, at which the multi-layer film is disposed, by greater than 2.0 nm, and reducing a root mean square roughness of an internal surface of the silicon membrane, defining at least a portion of the sealed cavity, by greater than 10.0 nm.

The example method can further comprise reducing a thickness of the silicon membrane, along a height direction of the silicon layer extending outward from a substrate at which the silicon layer is disposed, using a wet oxidation process.

The example method can further comprise forming a bumping pad of the silicon layer, adjacent to the silicon membrane and the cavity, using a wet oxidation process, where the bumping pad is defined by at least a raised portion of the silicon layer having an upper surface disposed at a greater distance from a base surface of the silicon layer than an outer surface of the silicon membrane.

### Example Operating Environment

FIG. 19 is a schematic block diagram of an operating environment 1900 with which the described subject matter can interact. The operating environment 1900 comprises one or more remote component(s) 1910. The remote component(s) 1910 can be hardware and/or software (e.g., threads, processes, computing devices). In one or more embodiments, remote component(s) 1910 can be a distributed computer system, connected to a local automatic scaling component and/or programs that use the resources of a distributed computer system, via communication framework 1940. Communication framework 1940 can comprise wired network devices, wireless network devices, mobile devices, wearable devices, radio access network devices, gateway devices, femtocell devices, servers, etc.

The operating environment 1900 also comprises one or more local component(s) 1920. The local component(s) 1920 can be hardware and/or software (e.g., threads, processes, computing devices). In one or more embodiments, local component(s) 1920 can comprise an automatic scaling component and/or programs that communicate/use the remote resources 1910 and 1920, etc., connected to a remotely located distributed computing system via communication framework 1940.

One possible communication between a remote component(s) 1910 and a local component(s) 1920 can be in the form of a data packet adapted to be transmitted between two or more computer processes. Another possible communication between a remote component(s) 1910 and a local component(s) 1920 can be in the form of circuit-switched data adapted to be transmitted between two or more computer processes in radio time slots. The operating environment 1900 comprises a communication framework 1940 that can be employed to facilitate communications between the remote component(s) 1910 and the local component(s) 1920, and can comprise an air interface, e.g., interface of a UMTS network, via an LTE network, etc. Remote component(s) 1910 can be operably connected to one or more remote data store(s) 1950, such as a hard drive, solid state drive, subscriber identity module (SIM) card, electronic SIM (eSIM), device memory, etc., that can be employed to store information on the remote component(s) 1910 side of communication framework 1940. Similarly, local component(s) 1920 can be operably connected to one or more local data store(s) 1930, that can be employed to store information on the local component(s) 1920 side of communication framework 1940.

### Example Computing Environment

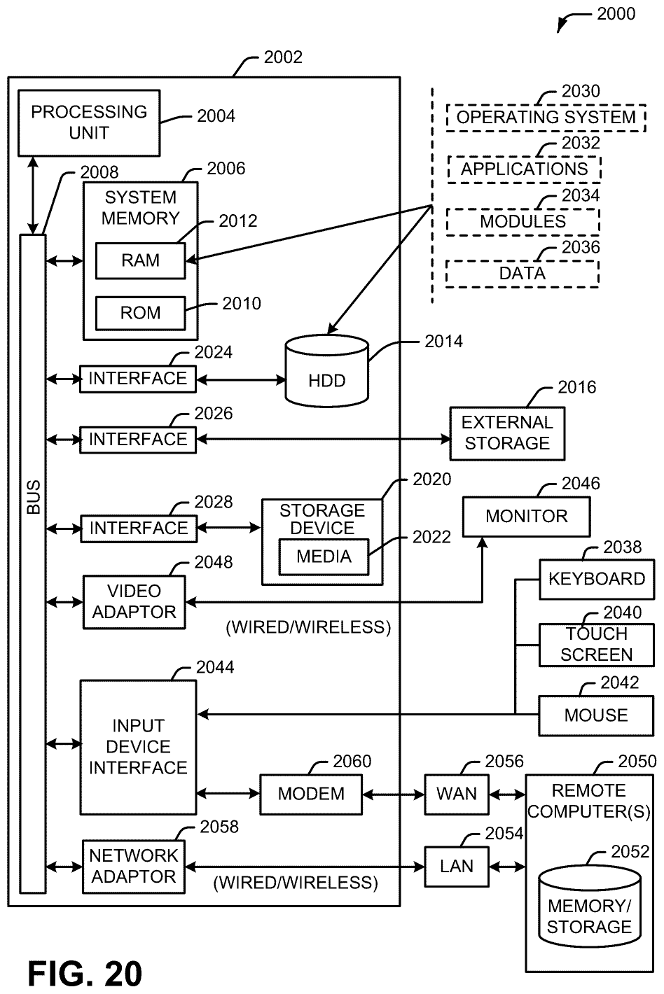

In order to provide additional context for various embodiments described herein, FIG. 20 and the following discussion are intended to provide a brief, general description of a suitable computing environment 2000 in which the various embodiments of the embodiment described herein can be implemented. While the embodiments have been described above in the general context of computer-executable instructions that can run on one or more computers, those skilled in the art will recognize that the embodiments can also be implemented in combination with other program modules and/or as a combination of hardware and software.

Generally, program modules include routines, programs, components, data structures, etc., that perform tasks or implement abstract data types. Moreover, the methods can be practiced with other computer system configurations, including single-processor or multiprocessor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can also be practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, and/or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data, or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible and/or non-transitory media which can be used to store desired information. In this regard, the terms “tangible” or “non-transitory” herein as applied to storage, memory, or computer-readable media, exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries, or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and include any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

Referring still to FIG. 20, the example computing environment 2000 which can implement one or more embodiments described herein includes a computer 2002, the computer 2002 including a processing unit 2004, a system memory 2006 and a system bus 2008. The system bus 1008 couples system components including, but not limited to, the system memory 1006 to the processing unit 2004. The processing unit 2004 can be any of various commercially available processors. Dual microprocessors and other multi-processor architectures can also be employed as the processing unit 2004.

The system bus 2008 can be any of several types of bus structure that can further interconnect to a memory bus (with or without a memory controller), a peripheral bus, and a local bus using any of a variety of commercially available bus architectures. The system memory 2006 includes ROM 2010 and RAM 2012. A basic input/output system (BIOS) can be stored in a non-volatile memory such as ROM, erasable programmable read only memory (EPROM), EEPROM, which BIOS contains the basic routines that help to transfer information between elements within the computer 2002, such as during startup. The RAM 2012 can also include a high-speed RAM such as static RAM for caching data.

The computer 2002 further includes an internal hard disk drive (HDD) 2014 (e.g., EIDE, SATA), and can include one or more external storage devices 2016 (e.g., a magnetic floppy disk drive (FDD) 2016, a memory stick or flash drive reader, a memory card reader, etc.). While the internal HDD 2014 is illustrated as located within the computer 2002, the internal HDD 2014 can also be configured for external use in a suitable chassis (not shown). Additionally, while not shown in computing environment 2000, a solid-state drive (SSD) could be used in addition to, or in place of, an HDD 2014.

Other internal or external storage can include at least one other storage device 2020 with storage media 2022 (e.g., a solid-state storage device, a nonvolatile memory device, and/or an optical disk drive that can read or write from removable media such as a CD-ROM disc, a DVD, a BD, etc.). The external storage 2016 can be facilitated by a network virtual machine. The HDD 2014, external storage device 2016 and storage device (e.g., drive) 2020 can be connected to the system bus 2008 by an HDD interface 2024, an external storage interface 2026 and a drive interface 2028, respectively.

The drives and their associated computer-readable storage media provide nonvolatile storage of data, data structures, computer-executable instructions, and so forth. For the computer 2002, the drives and storage media accommodate the storage of any data in a suitable digital format. Although the description of computer-readable storage media above refers to respective types of storage devices, other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 2012, including an operating system 2030, one or more application programs 2032, other program modules 2034 and program data 2036. All or portions of the operating system, applications, modules, and/or data can also be cached in the RAM 2012. The systems and methods described herein can be implemented utilizing various commercially available operating systems or combinations of operating systems.

Computer 2002 can optionally comprise emulation technologies. For example, a hypervisor (not shown) or other intermediary can emulate a hardware environment for operating system 2030, and the emulated hardware can optionally be different from the hardware illustrated in FIG. 20. In such an embodiment, operating system 2030 can comprise one virtual machine (VM) of multiple VMs hosted at computer 2002. Furthermore, operating system 2030 can provide runtime environments, such as the Java runtime environment or the .NET framework, for applications 2032. Runtime environments are consistent execution environments that allow applications 2032 to run on any operating system that includes the runtime environment. Similarly, operating system 2030 can support containers, and applications 2032 can be in the form of containers, which are lightweight, standalone, executable packages of software that include, e.g., code, runtime, system tools, system libraries and settings for an application.

Further, computer 2002 can be enabled with a security module, such as a trusted processing module (TPM). For instance, with a TPM, boot components hash next in time boot components, and wait for a match of results to secured values, before loading a next boot component. This process can take place at any layer in the code execution stack of computer 2002, e.g., applied at the application execution level or at the operating system (OS) kernel level, thereby enabling security at any level of code execution.

A user can enter commands and information into the computer 2002 through one or more wired/wireless input devices, e.g., a keyboard 2038, a touch screen 2040, and a pointing device, such as a mouse 2042. Other input devices (not shown) can include a microphone, an infrared (IR) remote control, a radio frequency (RF) remote control, or other remote control, a joystick, a virtual reality controller and/or virtual reality headset, a game pad, a stylus pen, an image input device, e.g., camera, a gesture sensor input device, a vision movement sensor input device, an emotion or facial detection device, a biometric input device, e.g., fingerprint or iris scanner, or the like. These and other input devices are often connected to the processing unit 2004 through an input device interface 2044 that can be coupled to the system bus 2008, but can be connected by other interfaces, such as a parallel port, an IEEE 1394 serial port, a game port, a USB port, an IR interface, a BLUETOOTH® interface, etc.

A monitor 2046 or other type of display device can also be connected to the system bus 2008 via an interface, such as a video adapter 2048. In addition to the monitor 2046, a computer typically includes other peripheral output devices (not shown), such as speakers, printers, etc.

The computer 2002 can operate in a networked environment using logical connections via wired and/or wireless communications to one or more remote computers, such as a remote computer 2050. The remote computer 2050 can be a workstation, a server computer, a router, a personal computer, portable computer, microprocessor-based entertainment appliance, a peer device or other common network node, and typically includes many or all of the elements described relative to the computer 2002, although, for purposes of brevity, only a memory/storage device 2052 is illustrated. The logical connections depicted include wired/wireless connectivity to a local area network (LAN) 2054 and/or larger networks, e.g., a wide area network (WAN) 2056. Such LAN and WAN networking environments are commonplace in offices and companies, and facilitate enterprise-wide computer networks, such as intranets, all of which can connect to a global communications network, e.g., the Internet.

When used in a LAN networking environment, the computer 2002 can be connected to the local network 2054 through a wired and/or wireless communication network interface or adapter 2058. The adapter 2058 can facilitate wired or wireless communication to the LAN 2054, which can also include a wireless access point (AP) disposed thereon for communicating with the adapter 2058 in a wireless mode.

When used in a WAN networking environment, the computer 2002 can include a modem 2060 or can be connected to a communications server on the WAN 2056 via other means for establishing communications over the WAN 2056, such as by way of the Internet. The modem 2060, which can be internal or external and a wired or wireless device, can be connected to the system bus 2008 via the input device interface 2044. In a networked environment, program modules depicted relative to the computer 2002 or portions thereof, can be stored in the remote memory/storage device 2052. The network connections shown are examples and other means of establishing a communications link between the computers can be used.

When used in either a LAN or WAN networking environment, the computer 2002 can access cloud storage systems or other network-based storage systems in addition to, or in place of, external storage devices 2016 as described above. Generally, a connection between the computer 2002 and a cloud storage system can be established over a LAN 2054 or WAN 2056 e.g., by the adapter 2058 or modem 2060, respectively. Upon connecting the computer 2002 to an associated cloud storage system, the external storage interface 2026 can, with the aid of the adapter 2058 and/or modem 2060, manage storage provided by the cloud storage system as it would other types of external storage. For instance, the external storage interface 2026 can be configured to provide access to cloud storage sources as if those sources were physically connected to the computer 2002.

The computer 2002 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a defined structure as with a conventional network or simply an ad hoc communication between at least two devices.

### CONCLUSION

The above description of illustrated embodiments of the one or more embodiments described herein, comprising what is described in the Abstract, is not intended to be exhaustive or to limit the described embodiments to the precise forms described. While one or more specific embodiments and examples are described herein for illustrative purposes, various modifications are possible that are considered within the scope of such embodiments and examples, as those skilled in the relevant art can recognize.

In this regard, while the described subject matter has been described in connection with various embodiments and corresponding figures, where applicable, other similar embodiments can be used or modifications and additions can be made to the described embodiments for performing the same, similar, alternative, or substitute function of the described subject matter without deviating therefrom. Therefore, the described subject matter should not be limited to any single embodiment described herein, but rather should be construed in breadth and scope in accordance with the appended claims below.

As it employed in the subject specification, the term “processor” can refer to substantially any computing processing unit or device comprising, but not limited to comprising, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit, a digital signal processor, a field programmable gate array, a programmable logic controller, a complex programmable logic device, a discrete gate or transistor logic, discrete hardware components, or any combination thereof designed to perform the functions described herein. Processors can exploit nano-scale architectures to optimize space usage or enhance performance of user equipment. A processor can also be implemented as a combination of computing processing units.

As used in this application, the terms “component,” “system,” “platform,” “layer,” “selector,” “interface,” and the like are intended to refer to a computer-related entity or an entity related to an operational apparatus with one or more functionalities, wherein the entity can be either hardware, a combination of hardware and software, software, or software in execution. As an example, a component may be, but is not limited to being, a process running on a processor, a processor, an object, an executable, a thread of execution, a program, and/or a computer. By way of illustration and not limitation, both an application running on a server and the server can be a component. One or more components may reside within a process and/or thread of execution and a component may be localized on one computer and/or distributed between two or more computers. In addition, these components can execute from various computer readable media having various data structures stored thereon. The components may communicate via local and/or remote processes such as in accordance with a signal having one or more data packets (e.g., data from one component interacting with another component in a local system, distributed system, and/or across a network such as the Internet with other systems via the signal). As another example, a component can be an apparatus with functionality provided by mechanical parts operated by electric or electronic circuitry, which is operated by a software or a firmware application executed by a processor, wherein the processor can be internal or external to the apparatus and executes at least a part of the software or firmware application. As yet another example, a component can be an apparatus that provides functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of these instances.

While the embodiments are susceptible to various modifications and alternative constructions, certain illustrated implementations thereof are shown in the drawings and have been described above in detail. However, there is no intention to limit the various embodiments to the one or more specific forms described, but on the contrary, the intention is to cover all modifications, alternative constructions, and equivalents falling within the spirit and scope.

In addition to the various implementations described herein, other similar implementations can be used, or modifications and additions can be made to the described implementation for performing the same or equivalent function of the corresponding implementation without deviating therefrom. Still further, multiple processing chips or multiple devices can share the performance of one or more functions described herein, and similarly, storage can be implemented across different devices. Accordingly, the various embodiments are not to be limited to any single implementation, but rather are to be construed in breadth, spirit, and scope in accordance with the appended claims.

What is claimed is:

1. An acoustic wave resonator, comprising:
a silicon layer comprising a base surface;
a multi-layer film disposed at the silicon layer opposite the base surface and comprising a metal electrode and a piezoelectric material; and
a cavity within the silicon layer, wherein the cavity is sealed, at a location opposite the base surface, by a silicon membrane.

2. The acoustic wave resonator of claim 1, wherein the silicon membrane and the silicon layer are a unitary element of the acoustic wave resonator.

3. The acoustic wave resonator of claim 1, wherein the multi-layer film further comprises a pair of metal electrodes, comprising the metal electrode, spaced apart from one another by the piezoelectric material disposed therebetween.

4. The acoustic wave resonator of claim 3, wherein the pair of metal electrodes comprises non-overlapping portions that are spaced from one another in a direction along the silicon layer.

5. The acoustic wave resonator of claim 1, further comprising:
a bumping pad defined by at least a raised portion of the silicon layer, the bumping pad comprising an upper surface disposed at a greater distance from the base surface than an outer surface of the silicon membrane.

6. The acoustic wave resonator of claim 1, wherein the multi-layer film and the sealed cavity are jointly configured to provide an S1 resonant mode between 1.0 GHz and 2.0 GHz and an A2 resonant mode greater than 3.0 GHz.

7. The acoustic wave resonator of claim 1, wherein the multi-layer film is disposed at an external surface of the silicon membrane, and wherein the external surface has a root mean square roughness of less than 0.5 nm.

8. The acoustic wave resonator of claim 1, wherein the acoustic wave resonator is one of a group of acoustic wave resonators fabricated at a silicon-on-insulator wafer platform, and wherein respective acoustic wave resonators of the group of acoustic wave resonators are fabricated to comprise respective controlled thickness ranges of respective silicon membranes of the respective acoustic wave resonators.

9. A batch of acoustic wave resonators fabricated using a common silicon-on-insulator wafer platform, each of the acoustic wave resonators comprising:
a silicon body disposed at the common silicon-on-insulator wafer platform and comprising:
a silicon layer adjacent the common silicon-on-insulator wafer platform,
a cavity defined within the silicon layer, and
a silicon membrane sealing the cavity,
wherein the silicon layer and the silicon membrane are provided as a unitary silicon element; and
a multi-layer film disposed at the silicon membrane opposite the common silicon-on-insulator wafer platform and comprising a pair of metal electrodes separated by a piezoelectric material.

10. The batch of acoustic wave resonators of claim 9, wherein, for each of the acoustic wave resonators, a thickness of a lower portion of the silicon layer, disposed between the cavity and the common silicon-on-insulator wafer platform, has a first thickness, in a direction outward from the common silicon-on-insulator wafer platform, that is greater than a thickness of the silicon membrane in the direction.

11. The batch of acoustic wave resonators of claim 9, wherein, for each of the acoustic wave resonators, an external surface of the silicon membrane, at which the multi-layer film is disposed, is disposed closer to the common silicon-on-insulator wafer platform than upper portions of the silicon layer disposed adjacent to the silicon membrane and the cavity.

12. The batch of acoustic wave resonators of claim 9, wherein, for each of the acoustic wave resonators, an external surface of the silicon membrane, at which the multi-layer film is disposed, has a root mean square roughness of less than 0.5 nm, and an internal surface of the silicon membrane, defining at least a portion of the cavity, has a root mean square roughness of less than 3.0 nm.

13. The batch of acoustic wave resonators of claim 9, wherein different ones of the acoustic wave resonators of the batch of acoustic wave resonators comprise sealed cavities with different sealed cavity volumes, the sealed cavities comprising:
a first set of sealed cavities each having a first volume within a first volume range corresponding to a first set of dimensions of first well arrays of first silicon wafers from which the first set of sealed cavities were formed, and
a second set of sealed cavities each having a second volume within a second volume range, different from the first volume range, corresponding to a second set of dimensions, different from the first set of dimensions, of second well arrays of second silicon wafers from which the second set of sealed cavities were formed.

14. The batch of acoustic wave resonators of claim 9, wherein different ones of the acoustic wave resonators of the batch of acoustic wave resonators comprise different silicon membranes with different thicknesses, the different thicknesses extending in a direction outward from the common silicon-on-insulator wafer platform, and the different silicon membranes comprising:
a first set of silicon membranes each having a first thickness within a first thickness range corresponding to a first time range over which a wet oxidation process was applied to the first set of silicon membranes, and
a second set of silicon membranes each having a second thickness within a second thickness range, different from the first thickness range, corresponding to a second time range, different from the first time range, over which the wet oxidation process was applied to the second set of silicon membranes.

15. A method for fabricating an acoustic wave resonator, the method comprising:
annealing a silicon wafer comprising a well array resulting in migration of silicon atoms of the silicon wafer and formation of a silicon layer having a cavity therewithin,
wherein the annealing the silicon wafer further results in migration of silicon atoms of the silicon wafer forming a silicon membrane extending over and sealing the cavity to result in a sealed cavity, and
wherein dimensions of the sealed cavity correspond to specified dimensions of the well array; and
applying a multi-layer film at the silicon layer and the silicon membrane.

16. The method of claim 15, further comprising:
smoothing of an external surface of the silicon membrane using a wet oxidation process.

17. The method of claim 16, wherein an external surface of the silicon membrane, at which the multi-layer film is disposed, results from the wet oxidation process, and wherein the external surface has a root mean square roughness of less than 0.5 nm.

18. The method of claim 16, wherein the using of the wet oxidation process comprises:
reducing a root mean square roughness of the external surface of the silicon membrane, at which the multi-layer film is disposed, by greater than 2.0 nm; and
reducing a root mean square roughness of an internal surface of the silicon membrane, defining at least a portion of the sealed cavity, by greater than 10.0 nm.

19. The method of claim 15, further comprising:
reducing a thickness of the silicon membrane, along a height direction of the silicon layer extending outward from a substrate at which the silicon layer is disposed, using a wet oxidation process.

20. The method of claim 15, further comprising:
forming a bumping pad of the silicon layer, adjacent to the silicon membrane and the cavity, using a wet oxidation process,
wherein the bumping pad is defined by at least a raised portion of the silicon layer having an upper surface disposed at a greater distance from a base surface of the silicon layer than an outer surface of the silicon membrane.
